(19) United States
(12) Patent Application Publication
(10) Pub. No.: US 2024/0222449 A1
(43) Pub. Date: Jul. 4, 2024

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Ta-Chun LIN, Hsinchu (TW); Chih-Hao CHANG, Hsinchu (TW); Jhon-Jhy LIAW, Zhudong Township (TW)

(73) Assignee: Taiwan Semiconductor Manufacturing Company, Ltd., Hsinchu (TW)

(21) Appl. No.: 18/150,027

(22) Filed: Jan. 4, 2023

(51) Int. Cl. H01L 29/417; H01L 29/06; H01L 29/08; H01L 29/40; H01L 29/423; H01L 29/66; H01L 29/775

(52) U.S. Cl. CPC H01L 29/41733; H01L 29/0673; H01L 29/0847; H01L 29/401; H01L 29/42392; H01L 29/66439; H01L 29/66545; H01L 29/775

(57) ABSTRACT

A method for manufacturing a semiconductor structure includes forming a fin over a substrate in a Z-direction. The fin includes first semiconductor layers and second semiconductor layers alternating stacked. The method further includes forming a dummy gate structure extending in a Y-direction and over the fin, forming a first source/drain feature and a second source/drain feature on opposite sides of the dummy gate structure in an X-direction, removing the dummy gate structure and the first semiconductor layers in the fin to form a gate trench, and forming a gate structure in the gate trench. The gate structure wraps around the second semiconductor layers. The method further includes forming a via in contact with a bottom surface of the first source/drain feature. The bottom surface of the first source/drain feature is lower than a bottom surface of the second source/drain feature.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been incorporated into memory devices (including, for example, static random-access memory, or SRAM, cells) and core devices (including, for example, standard logic, or STD, cells) to reduce chip footprint while maintaining reasonable processing margins. However, as GAA devices continue to be scaled down, conventional methods for manufacturing GAA devices may experience challenges. Accordingly, although existing technologies for fabricating GAA devices have been generally adequate for their intended purposes, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are perspective views of a workpiece at various fabrication stages, in accordance with some embodiments of the present disclosure.

FIGS. 1C-1, 1D-1, 1E-1, 1F-1, 1G-1, 1H-1, 1I-1, 1J-1, 1K-1, 1L-1, 1M-1, 1N-1, and 1O-1 are X-Z cross-sectional views of the workpiece at various fabrication stages along a line A-A′ of FIG. 1B, in accordance with some embodiments of the present disclosure.

FIGS. 1C-2, 1D-2, 1E-2, 1F-2, 1G-2, 1H-2, 1I-2, 1J-2, 1K-2, 1L-2, 1M-2, 1N-2, and 1O-2 are Y-Z cross-sectional views of the workpiece at various fabrication stages along a line B-B′ of FIG. 1B, in accordance with some embodiments of the present disclosure.

FIGS. 1C-3, 1D-3, 1E-3, 1F-3, 1G-3, 1H-3, 1I-3, 1J-3, 1K-3, 1L-3, 1M-3, 1N-3, and 1O-3 are Y-Z cross-sectional views of the workpiece at various fabrication stages along a line C-C′ of FIG. 1B, in accordance with some embodiments of the present disclosure.

FIG. 1P-1 is a top view (or a layout) of the workpiece at a fabrication stage, in accordance with some embodiments of the present disclosure.

FIG. 1P-2 is an X-Z cross-sectional view of the workpiece at the fabrication stages along a line A-A′ of FIG. 1P-1, in accordance with some embodiments of the present disclosure.

FIG. 1P-3 is a Y-Z cross-sectional view of the workpiece at various fabrication stages along a line B-B′ of FIG. 1P-1, in accordance with some embodiments of the present disclosure.

FIG. 1P-4 is a Y-Z cross-sectional view of the workpiece at various fabrication stages along a line C-C′ of FIG. 1P-1, in accordance with some embodiments of the present disclosure.

FIGS. 2A and 2B are X-Z cross-sectional views of the workpiece at various fabrication stages along a line A-A′ of FIG. 1B, in accordance with some alternative embodiments of the present disclosure.

FIGS. 3A, 4A, and 5A are top views (or layouts) of the workpiece at a fabrication stage, in accordance with some alternative embodiments of the present disclosure.

FIGS. 3B, 4B, and 5B are X-Z cross-sectional views of the workpiece at the fabrication stages along lines A-A′ of FIGS. 3A to 5A, respectively, in accordance with some alternative embodiments of the present disclosure.

FIGS. 3C, 4C, and 5C are Y-Z cross-sectional views of the workpiece at various fabrication stages along lines B-B′ of FIGS. 3A to 5A, respectively, in accordance with some alternative embodiments of the present disclosure.

FIGS. 3D, 4D, and 5D are Y-Z cross-sectional views of the workpiece at various fabrication stages along lines C-C′ of FIGS. 3A to 5A, respectively, in accordance with some alternative embodiments of the present disclosure.

FIGS. 6A, 7A, 8A, 9A, 10A, 11A, 12A, 13A, 14A, 15A, and 16A are X-Z cross-sectional views of the workpiece at the fabrication stages along lines A-A′ of FIGS. 1B, 1P-1, or 3A to 5A, in accordance with some alternative embodiments of the present disclosure.

FIGS. 6B, 7B, 8B, 9B, 10B, 11B, 12B, 13B, 14B, 15B, and 16B are Y-Z cross-sectional views of the workpiece at various fabrication stages along lines B-B′ of FIGS. 1B, 1P-1, or 3A to 5A, in accordance with some alternative embodiments of the present disclosure.

FIGS. 6C, 7C, 8C, 9C, 10C, 11C, 12C, 13C, 14C, 15C, and 16C are Y-Z cross-sectional views of the workpiece at various fabrication stages along lines C-C′ of FIGS. 1B, 1P-1, or 3A to 5A, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications. While existing technologies for fabricating GAA transistors have been generally adequate for their intended applications, they have not been entirely satisfactory in all aspects.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including back-side sheet via to prevent shorting to gate structure. Further, the back-side sheet via may be designed to have a larger volume (or a larger cross-sectional area) to reduce or decrease resistance and increase the process window. The details of the structure and manufacturing methods of the present disclosure are described below in conjunction with the accompanying drawings, which illustrate the process of making GAA transistors, according to some embodiments.

As GAA transistors and circuit cells in device region continue to be scaled down, the space over each GAA transistors and circuit cells decreases. As such, interconnection structure and routing over the device region (or at front-side of the device region) uses too many routing resources, thereby increasing resistance of the interconnection structure and therefore impact the cell scaling as well as cell performance. In order to relieve the crowded space at the front-side interconnection structure, some interconnection routing are designed under the device region (or at back-side of the device region). However, due to process variation for forming via at back-side of the device region (referred to as back-side via), the back-side via may be shifted from the desired position, so that the back-side via may make contact with the gate structure, causing a short-circuit. This would cause a failure of the GAA transistor in the memory (e.g., SRAM) or the standard logic cell, thereby decreasing the yield. Therefore, an improved design for a back-side via is needed.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise excepted.

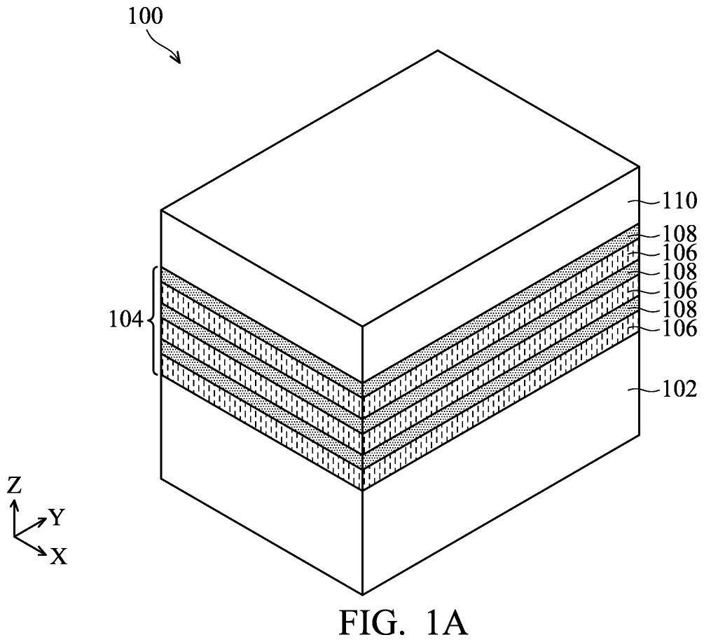

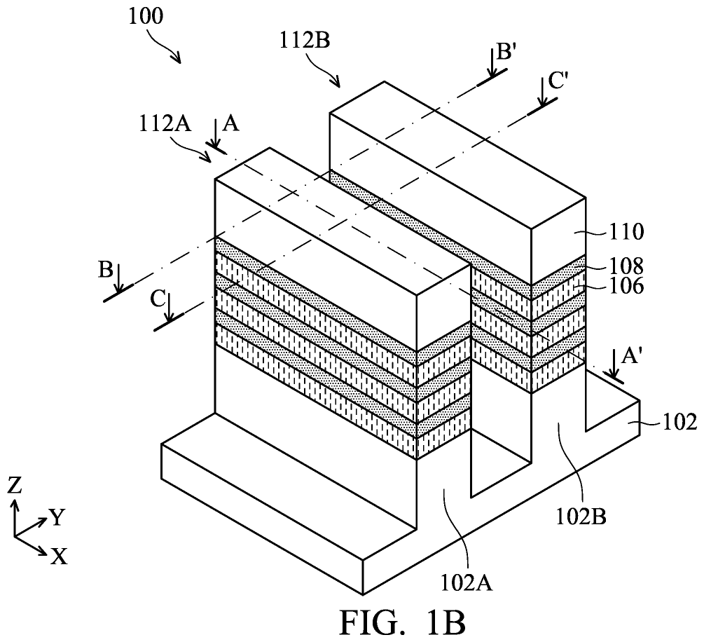

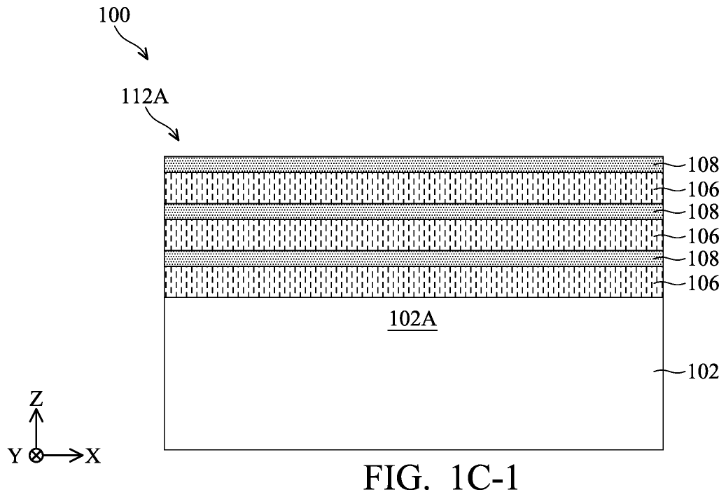

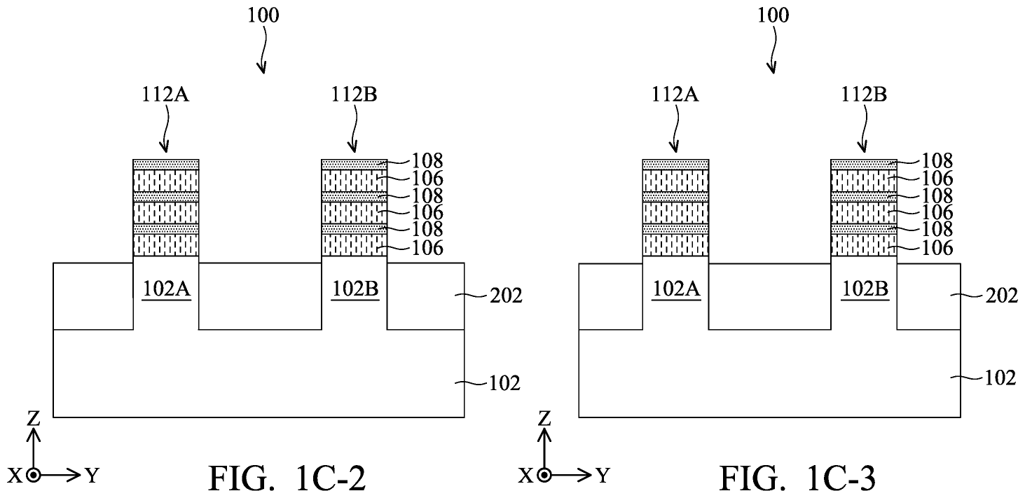

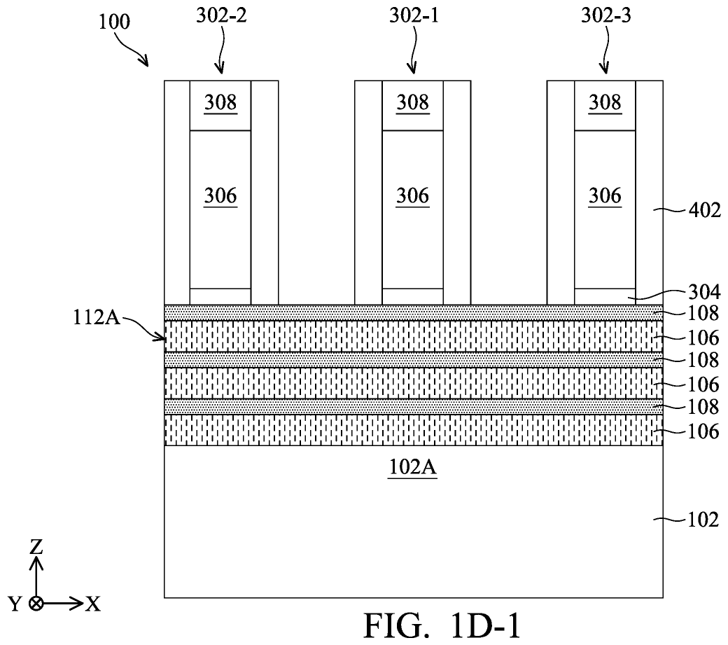

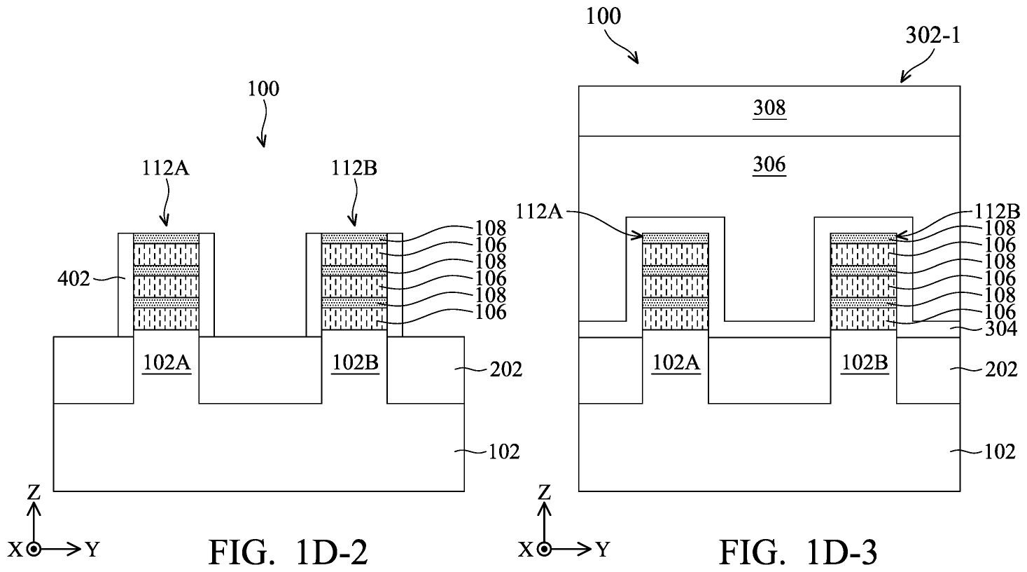

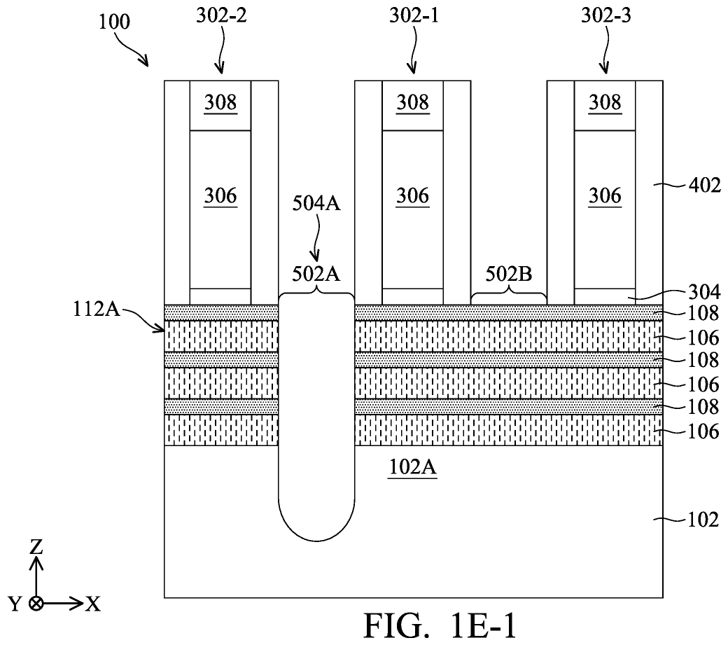

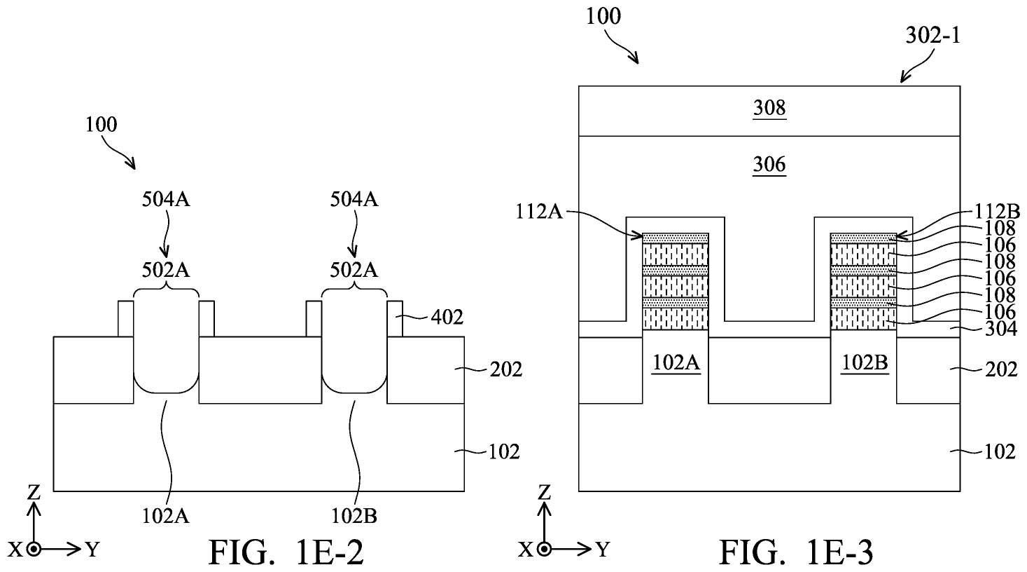

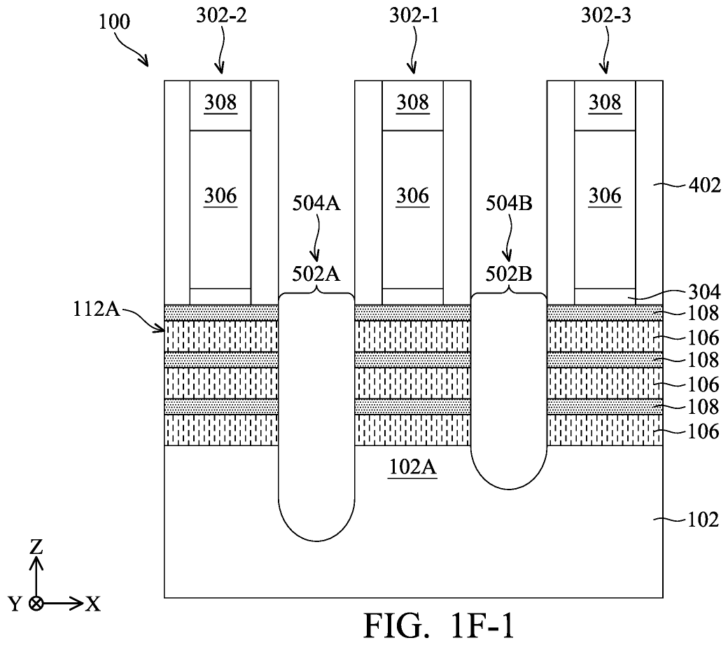

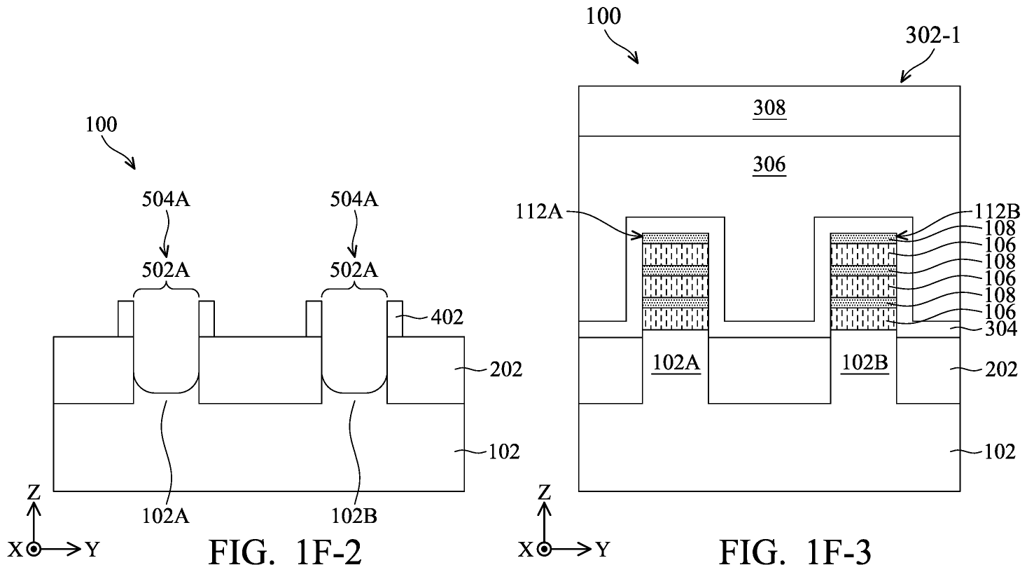

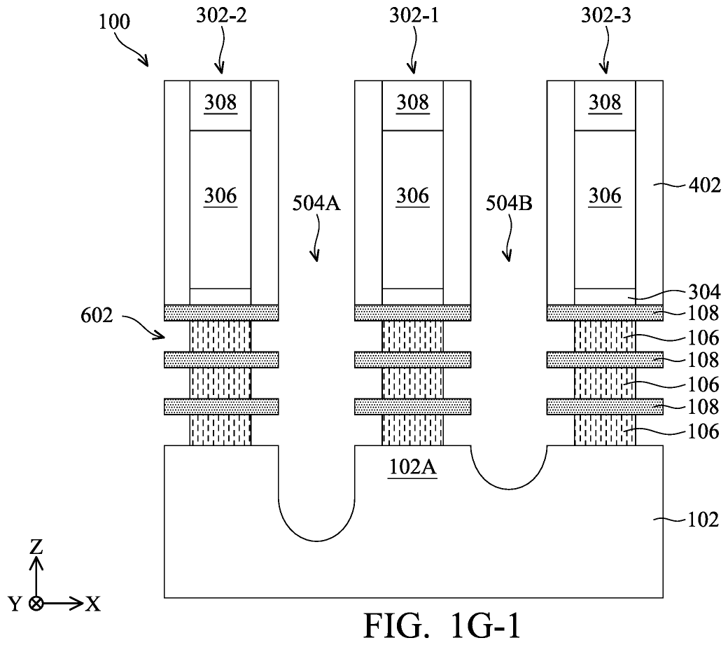

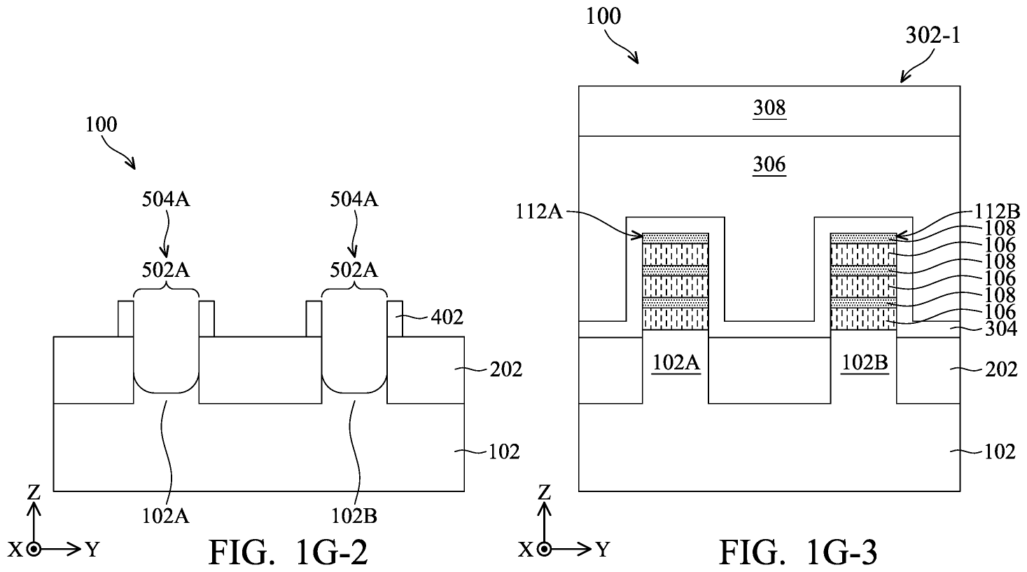

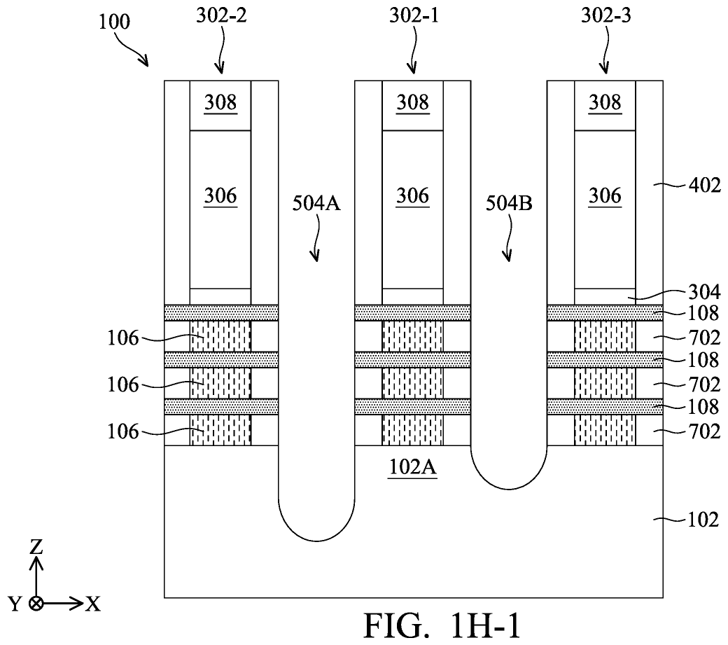

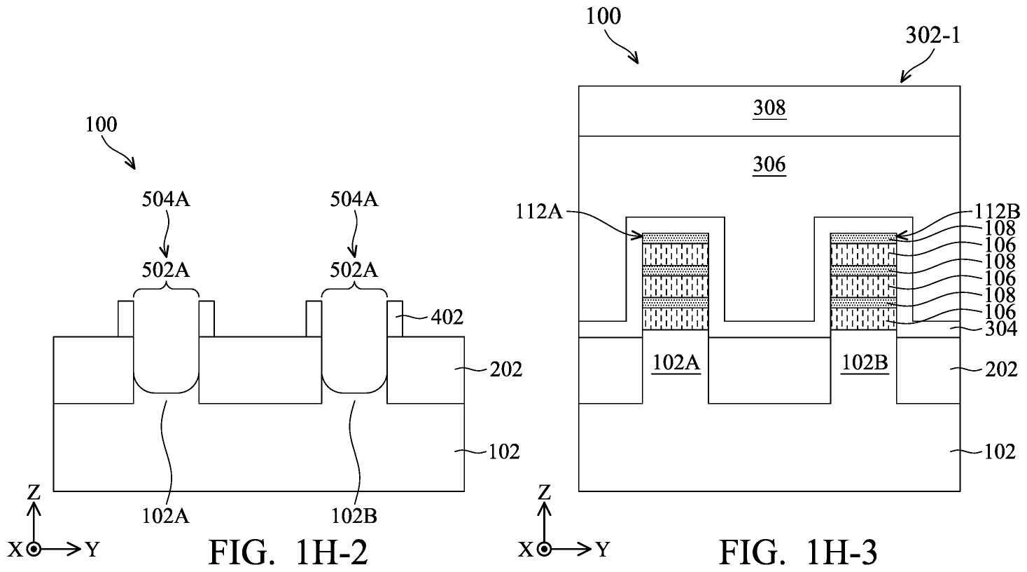

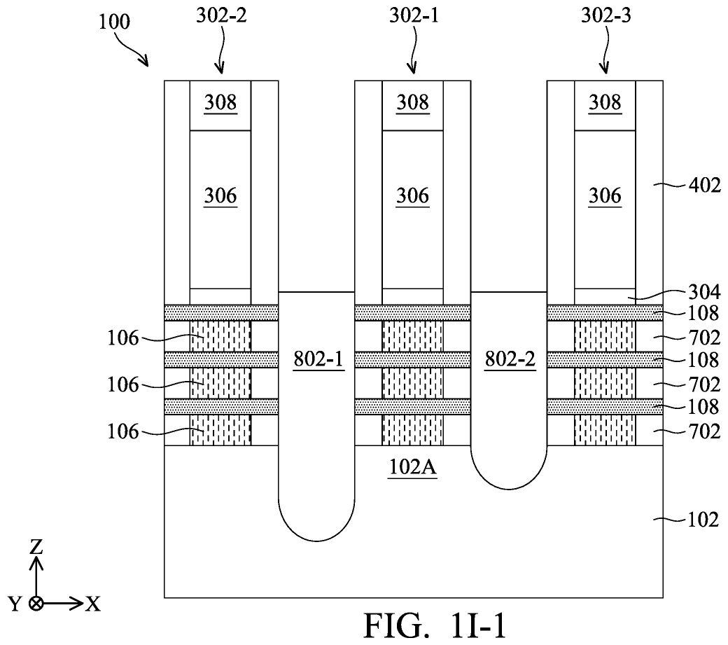

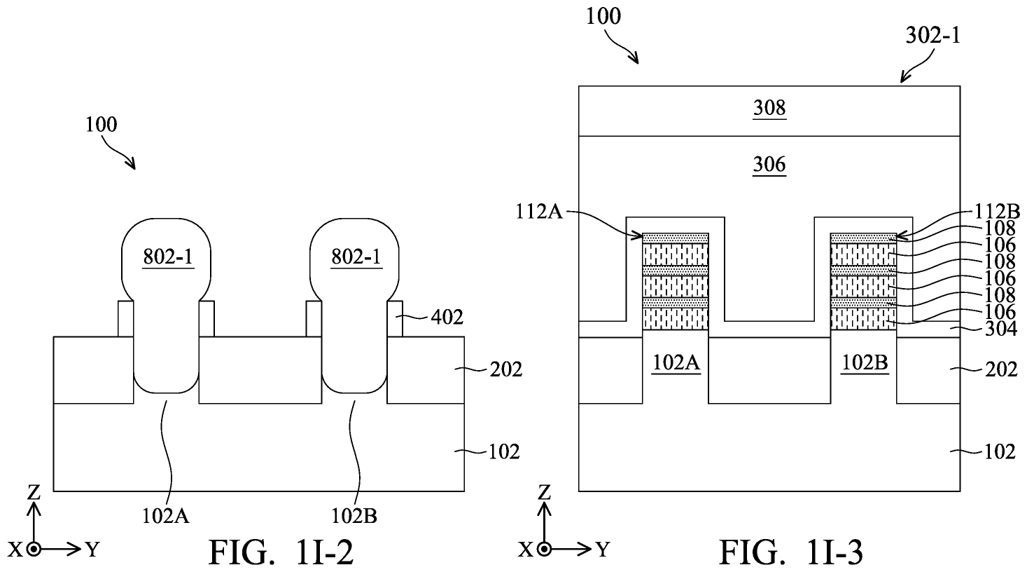

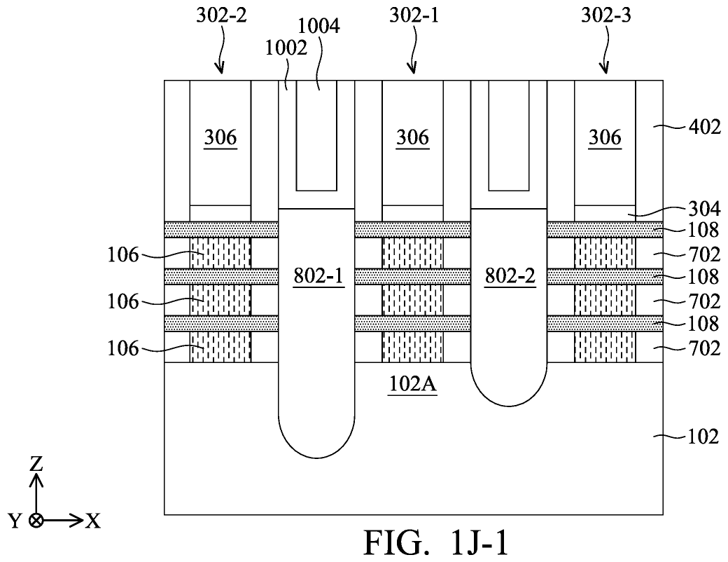

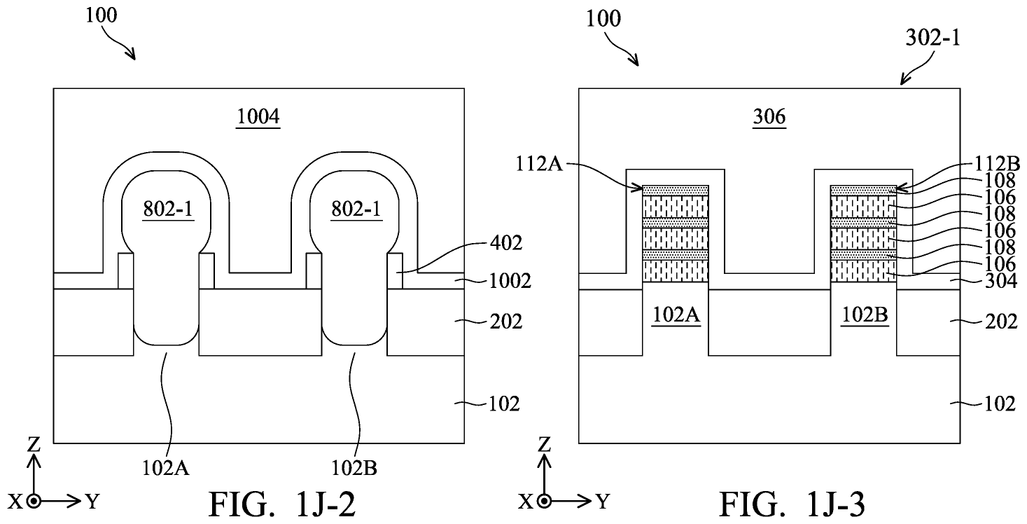

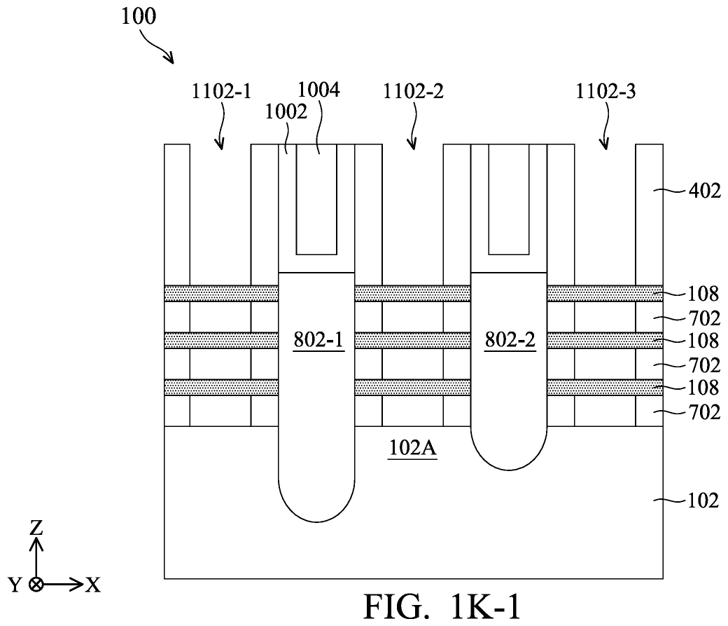

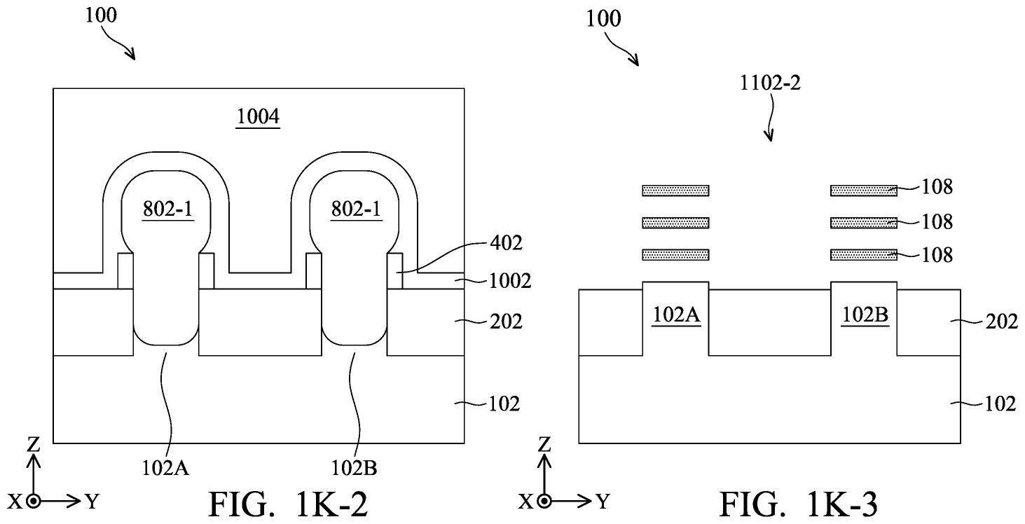

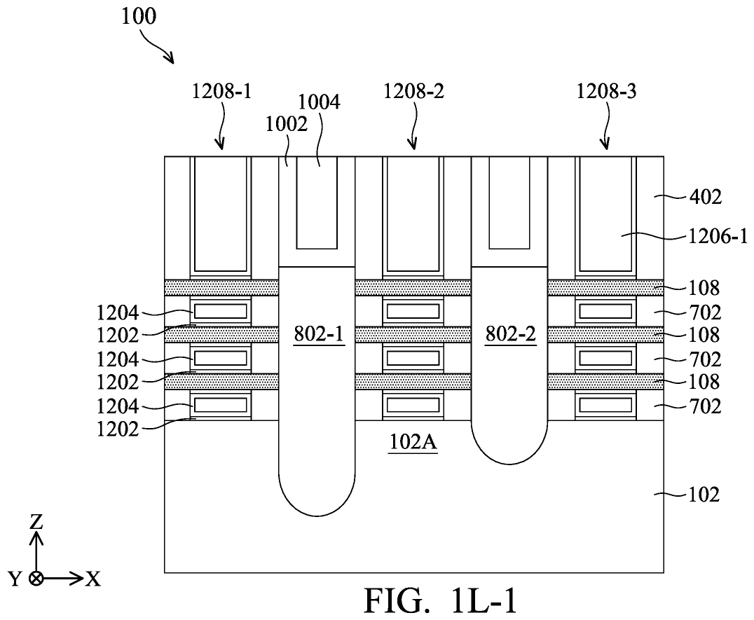

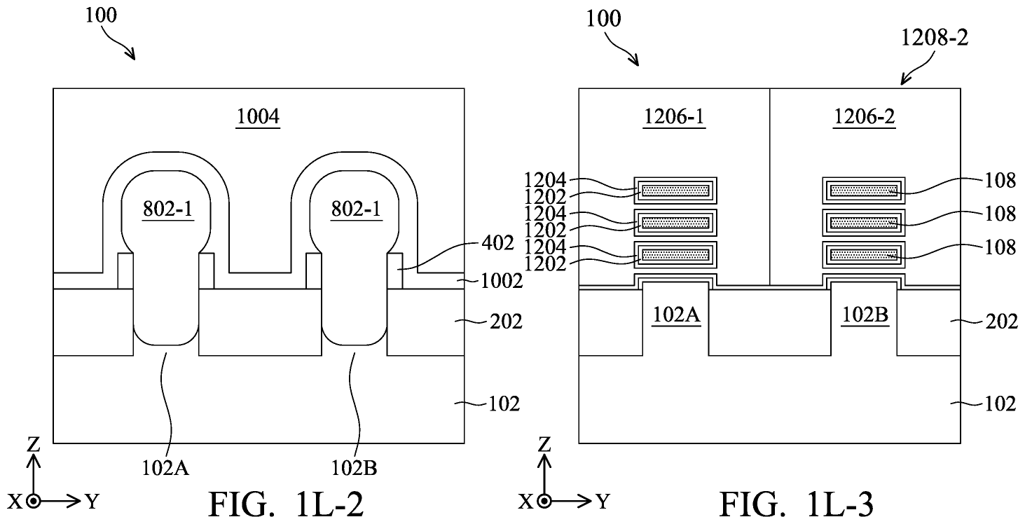

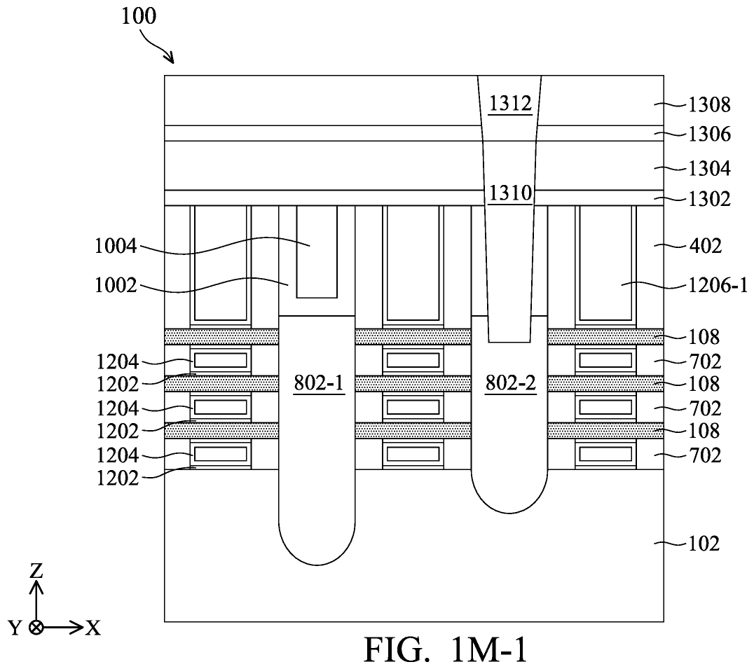

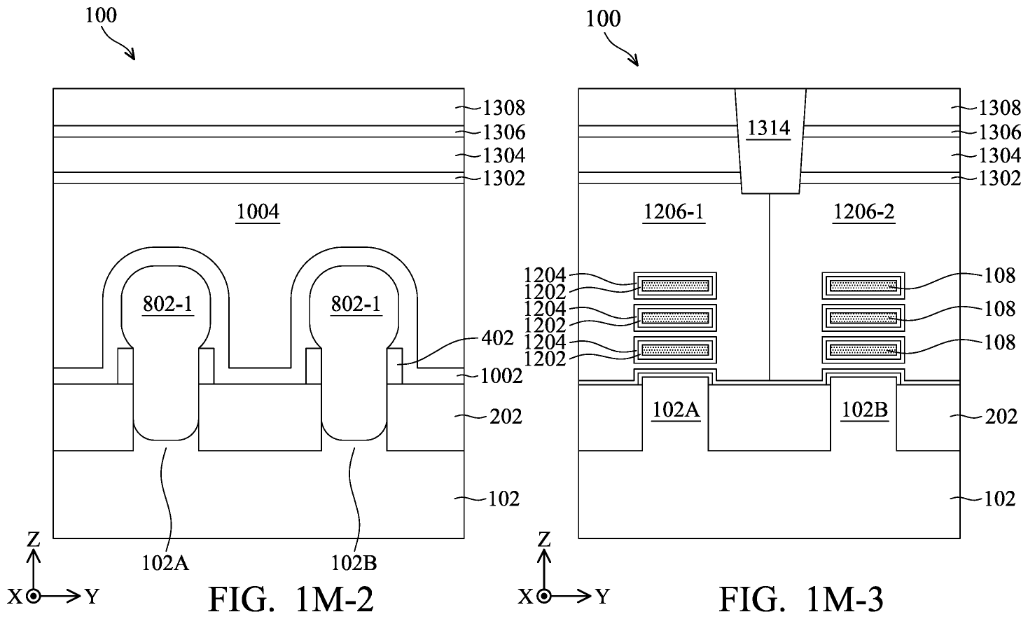

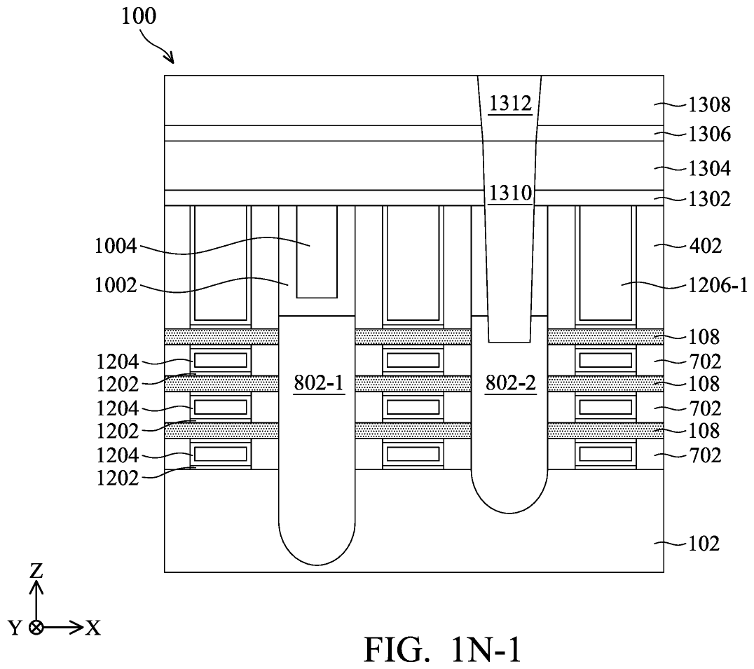

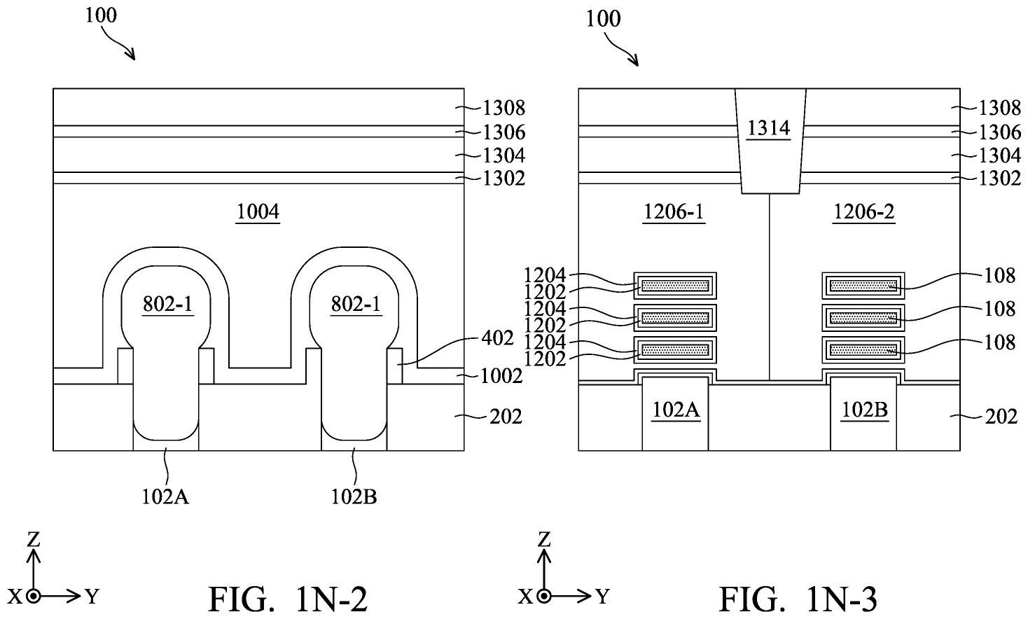

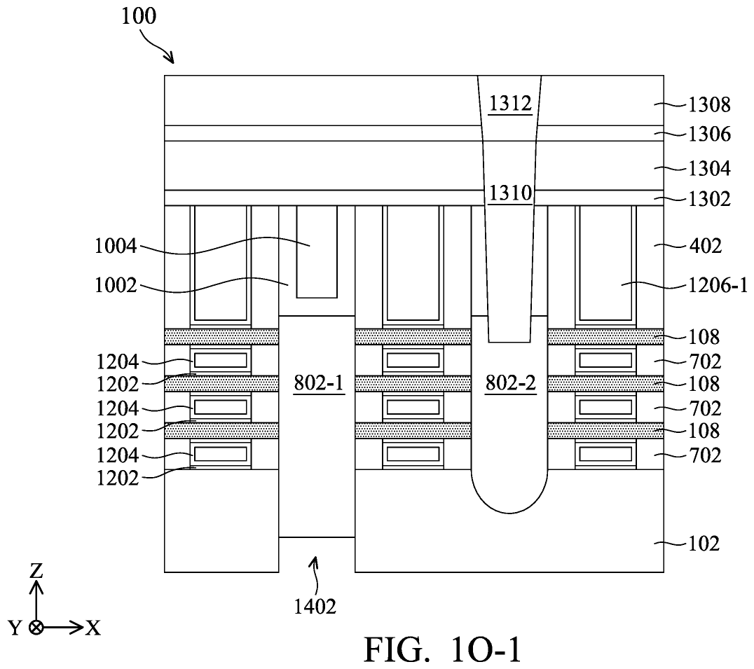

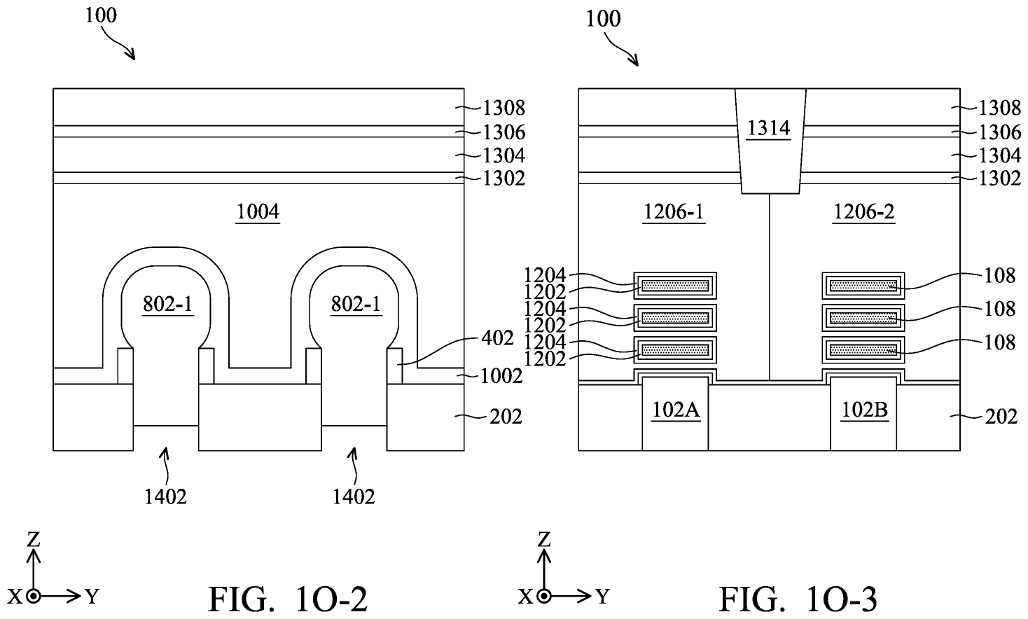

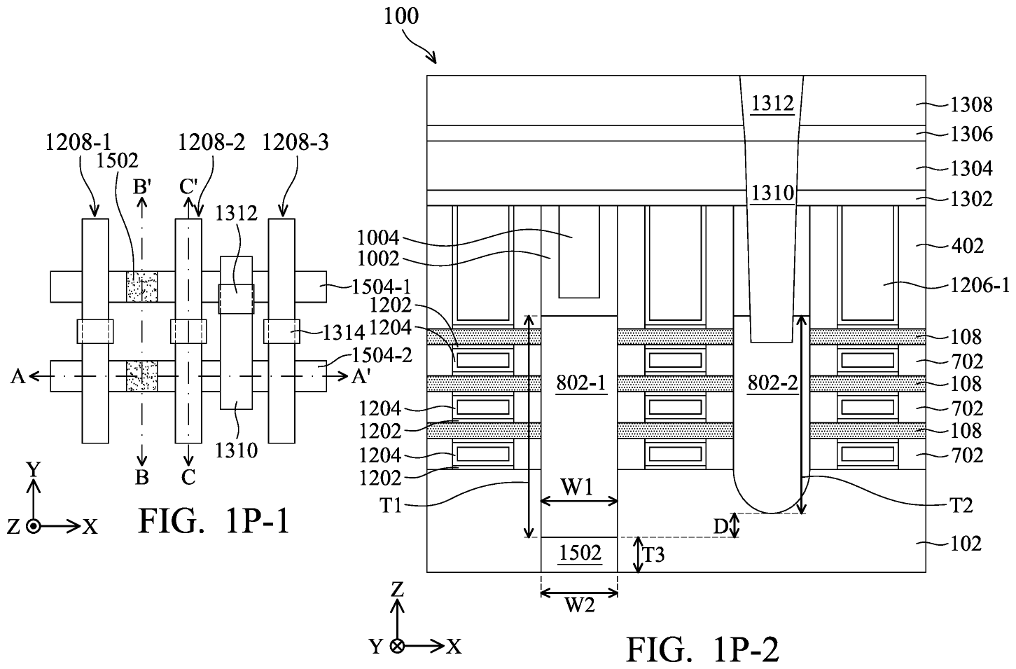

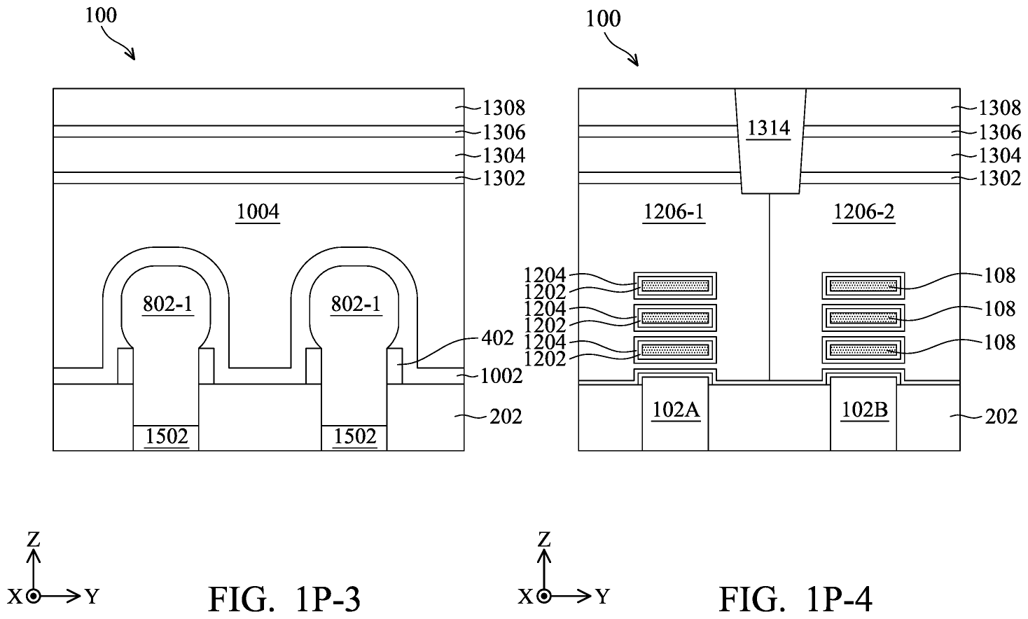

FIGS. 1A and 1B are perspective views of a workpiece 100 at various fabrication stages, in accordance with some embodiments of the present disclosure. Referring to FIGS. 1A, a workpiece 100 is provided. As shown in FIG. 1A, the workpiece 100 includes a substrate 102 and a stack 104 over the substrate 102. In some embodiments, the substrate 102 contains a semiconductor material, such as bulk silicon (Si). In some other embodiments, the substrate 102 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 102 may also include an insulating layer, such as a silicon oxide layer, to have a silicon-on-insulator (SOI) structure or a germanium-on-insulator (GOI) structure. In some embodiments, the substrate 102 may include one or more well regions, such as n-type well regions doped with an n-type dopant (i.e., phosphorus (P) or arsenic (As)) or p-type well regions doped with a p-type dopant (i.e., boron (B)), for forming different types of devices. The doping the n-type wells and the p-type wells may be formed using ion implantation or thermal diffusion. In some embodiments, n-type wells have an n-type dopant concentration of about 5×10¹⁶ cm⁻³ to about 5×10¹⁹ cm⁻³, and p-type wells have a p-type dopant concentration of about 5×10¹⁶ cm⁻³ to about 5×10¹⁹ cm⁻³. Because the workpiece 100 will be fabricated into a semiconductor structure 100 upon conclusion of the fabrication processes, the workpiece 100 may be referred to as the semiconductor structure 100 as the context requires.

The stack 104 includes semiconductor layers 106 and 108, and the semiconductor layers 106 and 108 are alternatingly stacked in the Z-direction. The semiconductor layers 106 and the semiconductor layers 108 may have different semiconductor compositions. In some embodiments, semiconductor layers 106 are formed of silicon germanium (SiGe) and the semiconductor layers 108 are formed of silicon (Si). In these embodiments, the additional germanium content in the semiconductor layers 106 allow selective removal or recess of the semiconductor layers 106 without substantial damages to the semiconductor layers 108, so that the semiconductor layers 106 are also referred to as sacrificial layers. In some embodiments, the semiconductor layers 106 and 108 are epitaxially grown over (on) the substrate 102 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 106 and the semiconductor layers 108 are deposited alternatingly, one-after-another, to form the stack 104. It should be noted that three (3) layers of the semiconductor layers 106 and three (3) layers of the semiconductor layers 108 are alternately and vertically arranged (or stacked) as shown in FIG. 1A, which are for illustrative purposes only and not intended to be limiting beyond what is specifically recited in the claims. The number of layers depends on the desired number of channels members for the semiconductor device. In some embodiments, there may be from 2 to 10 semiconductor layers 106 alternating with 2 to 10 semiconductor layers 108 in the stack 104.

For patterning purposes, the workpiece 100 may also include a hard mask layer 110 over the stack 104. The hard mask layer 110 may be a single layer or a multi-layer. In some embodiments, the hard mask layer 110 is a single layer and includes a silicon germanium layer. In some embodiments, the hard mask layer 110 is a multi-layer and includes a silicon nitride layer and a silicon oxide layer over the silicon nitride layer. In some other embodiments, the hard mask layer 110 is a multi-layer and includes a silicon germanium layer and a silicon layer over the silicon germanium layer.

Referring to FIG. 1B, the substrate 102, the stack 104, and the hard mask layer 110 are then patterned to form fins 112A and 112B (may be collectively referred to as fins 112) over the substrate 102. As shown in FIG. 1B, each of the fins 112 includes a base fin (102A and 102B) formed from a portion of the substrate 102 and a stack portion formed from the stack 104 over the base portion. In some aspects, the base fins 102A and 102B protrude from the substrate 102. Each of the fins 112 extends lengthwise in the X-direction and extends vertically in the Z-direction over the substrate 102, and arranged in the Y-direction. In some embodiments, widths of the fins 112 along the Y-direction are the same. Although the two fins 112A and 112B are formed and shown herein, more fins may be formed, such as three or more fins.

The fins 112 may be patterned using suitable processes including double-patterning or multi-patterning processes. For example, in some embodiments, a material layer is formed over a substrate and patterned using a photolithography process. Spacers are formed alongside the patterned material layer using a self-aligned process. The material layer is then removed, and the remaining spacers, or mandrels, may then be used to pattern the fins 112 by etching the stack 104 and the substrate 102. The etching process may include dry etching, wet etching, reactive ion etching (RIE), and/or other suitable processes.

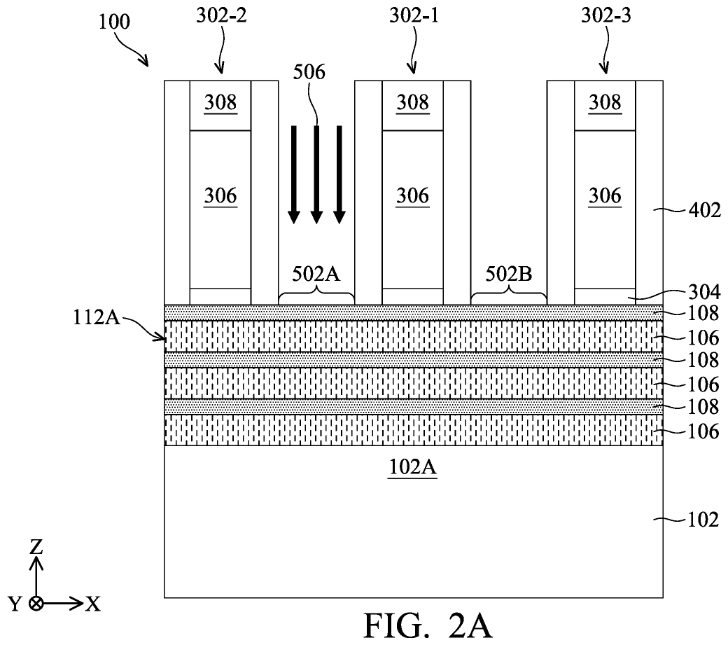

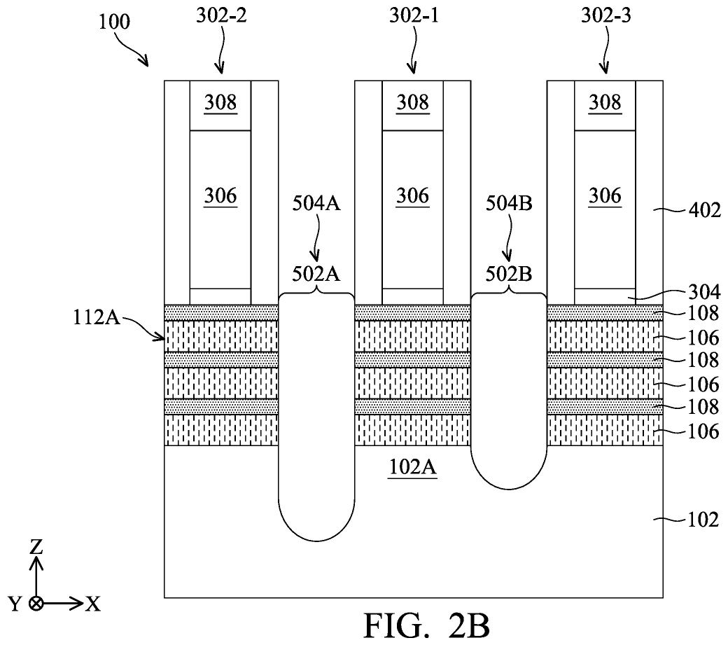

FIGS. 1C-1 to 1O-1 are X-Z cross-sectional views of the workpiece 100 at various fabrication stages along a line A-A′ of FIG. 1B, in accordance with some embodiments of the present disclosure. FIGS. 1C-2 to 1O-2 are Y-Z cross-sectional views of the workpiece 100 at various fabrication stages along a line B-B′ of FIG. 1B, in accordance with some embodiments of the present disclosure. FIGS. 1C-3 to 1O-3 are Y-Z cross-sectional views of the workpiece 100 at various fabrication stages along a line C-C′ of FIG. 1B, in accordance with some embodiments of the present disclosure.

Referring to FIGS. 1C-1 to 1C-3, an isolation structure 202 is formed. After the fins 112 are formed, the hard mask layer 110 over the fins 112 is removed and the isolation structure 202 is formed over the substrate 102. In some embodiments, the isolation structure 202 is formed between the fins 112. In some other aspects, the isolation structure 202 is formed around the fins 112. More specifically, the isolation structure 202 is formed between and around the base fins (e.g., 102A and 102B) of the fins 112. The isolation structure 202 may also be referred to as shallow trench isolation (STI) feature. In some embodiments, a dielectric material for the isolation structure 202 is first deposited over the workpiece 100. Specifically, the dielectric material is deposited and formed over the fins 112 and the substrate 102 to cover the fins 112 and the substrate 102. In some aspects, the dielectric material is formed to wrap around the fins 112. In some embodiments, the dielectric material may include silicon oxide, silicon nitride, silicon oxynitride, fluorine-doped silicate glass (FSG), a low-k dielectric, combinations thereof, and/or other suitable materials. In various embodiments, the dielectric material may be deposited by a CVD, a subatmospheric CVD (SACVD), a flowable CVD (FCVD), an ALD, spin-on coating, and/or other suitable process. The deposited dielectric material is then thinned and planarized, for example by a chemical mechanical polishing (CMP) process, until top surfaces of the hard mask layer 110 is exposed (not shown). The planarized dielectric material is further recessed by a dry etching process, a wet etching process, and/or a combination thereof to form the isolation structure 202. As shown in FIG. 1C, the stack portions of the fins 112 rise above the isolation structures 202 while the base fins 102A and 102B are surrounded by the isolation structures 202. In other words, top surfaces (or topmost surfaces) of the substrate 102 are higher than top surfaces of the isolation structure 202. In some embodiments, before the formation of the isolation structure 202, a liner layer may be conformally deposited over the substrate 202 using ALD or CVD.

Referring to FIGS. 1D-1 to 1D-3, dummy gate structures 302-1 to 302-3 (may be collectively referred to as dummy gate structures 302) may be formed over the fin 112 and over the isolation structure 202. The dummy gate structures 302 may be configured to extend lengthwise in the Y-direction and wrap around top surfaces and side surfaces of the fins 112, as shown in FIG. 1D-3. In some embodiments, to form the dummy gate structures 302, a dummy interfacial material for dummy interfacial layers 304 is first formed over fins 112 and over the isolation structure 202. More specifically, the dummy interfacial material is conformally formed on the sidewalls of the fins 112 and over the top surfaces of the fins 112 and the isolation structure 202, as shown in FIG. 1D-3. In some embodiments, the dummy interfacial layer 304 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material for dummy gate electrodes 306 is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof. The dummy gate material and/or the dummy interfacial material may be formed by way of a thermal oxidation process and/or a deposition process (e.g., physical vapor deposition (PVD), CVD, PECVD, and ALD).

Then, hard mask layers 308 are formed over the dummy gate material. In some embodiments, the hard mask layers 308 may be formed using photolithography and removal (e.g., etching) processes. In some embodiments, the hard mask layers 308 may include photoresist materials or hard mask materials. In some embodiments, each of the hard mask layers 308 may include multiple layers, such as a silicon nitride layer and a silicon oxide layer. After the formation of the hard mask layers 308, a removal process (e.g., etching) may be performed to remove portions of the dummy gate material for the dummy gate electrodes 306 and the dummy interfacial material for the dummy interfacial layers 304 that do not directly underlie the hard mask layers 308, thereby forming the dummy gate structures 302 each having the dummy interfacial layer 304, the dummy gate electrode 306, and the hard mask layer 308. The dummy interfacial layers 304 may also be referred to as dummy gate dielectrics. The dummy gate structures 302 may undergo a gate replacement process through subsequent processing to form metal gates, such as a high-k metal gate, as discussed in greater detail below.

FIG. 1D-1 shows three dummy gate structures 302-1 to 302-3. In some embodiments, less or more dummy gate structures may be formed for one or more transistors sharing source/drain regions. In other embodiments, some dummy gate structures may also undergo a gate replacement process to form dielectric based gates that electrically isolate transistors formed by the dummy gate structure 302 from neighboring transistors or devices. For examples, dummy gate structures 302-2 and 302-3 may be replaced with dielectric material in sequent processes to form dielectric based gates to isolate resultant transistor formed from the dummy gate structure 302-1 from neighboring transistors or devices.

Still referring to FIGS. 1D-1 to 1D-3, after the formation of the dummy gate structures 302, gate spacers 402 are formed on sidewalls of the dummy gate structures 302, over the top surfaces of the fins 112, and on the sidewalls of the fins 112. More specifically, the gate spacers 402 are formed on opposite the sidewalls of the fins 112, as shown in FIG. 1D-2, and formed on opposite the sidewalls of the dummy gate structures 302, as shown in FIG. 1D-1. The gate spacers 402 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), carbon doped oxide, nitrogen doped oxide, porous oxide, or combinations thereof. The gate spacers 402 may include a single layer or a multi-layer structure. In some embodiments, the gate spacers 402 may be formed by conformally depositing a spacer layer (containing the dielectric material) over the isolation structure 202, the fins 112, and dummy gate structures 302, followed by an anisotropic etching process to remove top portions of the spacer layer from the top surfaces of the isolation structure 202, the fins 112, and dummy gate structures 302. After the etching process, portions of the spacer layer on the sidewall surfaces of the fins 112 and the dummy gate structures 302 substantially remain and become the gate spacers 402. In some embodiments, the anisotropic etching process is a dry (e.g., plasma) etching process. Additionally or alternatively, the formation of the gate spacers 402 may also involve chemical oxidation, thermal oxidation, ALD, CVD, and/or other suitable methods. The gate spacers 402 may also be interchangeably referred to as top spacers.

Referring to FIGS. 1E-1 to 1E-3, first regions 502A of the fins 112 are recessed to form source/drain trenches 504A in the fins 112 (or passing through the semiconductor layers 106 and 108) for source/drain regions. Specifically, the source/drain trenches 504A may be formed by performing one or more etching processes to remove portions of the semiconductor layers 106, the semiconductor layers 108, and the substrate 102 (base fins 102A and 102B) in the first regions 502A of the fins 112 that do not vertically overlap or be covered by the dummy gate structure 302 and the gate spacers 402 on opposite the sidewalls of the gate structure 302, while second regions 502B of the fins 112 may be covered by a mask layer (not shown, may include photoresist materials or hard mask materials) during the etching processes.

Referring to FIGS. 1F-1 to 1F-3, after the formation of the source/drain trenches 504A, second regions 502B of the fins 112 are recessed to form source/drain trenches 504B in the fins 112 (or passing through the semiconductor layers 106 and 108) for source/drain regions. Similarly, the source/drain trenches 504B may be formed by performing one or more etching processes to remove portions of the semiconductor layers 106, the semiconductor layers 108, and the substrate 102 (base fins 102A and 102B) in the second regions 502B of the fins 112 that do not vertically overlap or be covered by the dummy gate structure 302 and the gate spacers 402 on opposite the sidewalls of the gate structure 302, while the first regions 502A of the fins 112 may be covered by a mask layer (not shown, may include photoresist materials or hard mask materials) during the etching processes. As shown in FIG. 1F-1, a depth of the source/drain trenches 504A in the fins 112 is greater than a depth of the source/drain trenches 504B in the fins 112. In other words, bottom surfaces of the source/drain trenches 504A are lower than bottom surfaces of the source/drain trenches 504B.

Subsequent source/drain features will be formed in the first regions 502A and the second regions 502B, and thus the first regions 502A and the second regions 502B may be referred to as source/drain regions. In some embodiments, a single etchant may be used to remove the semiconductor layers 106, the semiconductor layers 108, and the substrate 102 in the first regions 502A and the second regions 502B of the fins 112, whereas in other embodiments, multiple etchants may be used to perform the etching process. After the recessing, sidewalls of the semiconductor layers 106 and 108 that vertically overlap or be covered by the dummy gate structure 302 and the gate spacers 402 are exposed in the source/drain trenches 504A and 504B, as shown in FIGS. 1F-1. In some embodiments, top portions of the gate spacers on the sidewalls of the fins 112 are also removed, as shown in FIG. 1F-1. In other embodiments, although not shown in FIG. 1F-2, top portions of the hard mask layer 310 and the gate spacers on the sidewalls of the dummy gate structure 302 are removed, lowering the height of the dummy gate structure 302 (the hard mask layer 310) and the height of the gate spacers.

In the embodiments shown in FIGS. 1E-1 to 1E-3 and 1F-1 to 1F-3, the source/drain trenches 504A and 504B are separately formed to obtain different depths of the source/drain trenches 504A and 504B. In some embodiments, the source/drain trenches 504A and 504B may be formed simultaneously. Specifically, after the formation of the dummy gate structures 302 and the gate spacers 402 (shown in FIGS. 1D-1 to 1D-3), instead of etching the first region 502A for forming the source/drain trenches 504A at first, one or more ion implantation processes 506 are performed to implant dopants in the first regions 502A at first for modulating structures or properties of the semiconductor layers 106 and 108 of the fins 112 in the first regions 502A, as shown in FIG. 2A. For examples, the structures of the fins 112 in the first regions 502A undergo the ion implantation processes 506 may be more easily etched. Then, one or more etching processes may be performed to recess or etching the first regions 502A and the second regions 502B of the fins 112 simultaneously to form the source/drain trenches 504A and 504B, as shown in FIG. 2B. In some embodiments, the dopants used in the ion implantation processes 506 may include Si, Ge, N, Ar, C, P, As, B, or combinations thereof.

Referring to FIGS. 1G-1 to 1G-3, side portions of the semiconductor layers 106 are removed via a selective etching process. Specifically, the selective etching process is performed that selectively etches the side portions of the semiconductor layers 106 below the gate spacers 402 through the source/drain trenches 504A and 504B, with minimal (or no) etching of semiconductor layers 108, such that gaps 602 are formed between the semiconductor layers 108 as well as between the semiconductor layers 108 and the substrate 102, below the gate spacers 402. The etching process is configured to laterally etch (e.g., along the X-direction) the semiconductor layers 106 below the gate spacers 710. The selective etching process is a dry etching process, a wet etching process, other suitable etching process, or combinations thereof.

Referring to FIGS. 1H-1 to 1H-3, inner spacers 702 are formed to fill the gaps 602. In some embodiments, sidewalls of the inner spacers 702 are aligned to the sidewalls of the gate spacers 402 and the semiconductor layers 108, as shown in FIG. 1H-1. In order to form the inner spacers 702, a deposition process forms a spacer layer into the source/drain trenches 504A and 504B and the gaps 602, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 504A and 504B. The deposition process is configured to ensure that the spacer layer fills the gaps 602 between the semiconductor layers 108 as well as between the semiconductor layer 108 and the substrate 102 under the gate spacers 402. An etching process is then performed that selectively etches the spacer layer to form inner spacers 702 (as shown in FIG. 1H-1) with minimal (to no) etching of the semiconductor layer 108, the substrate 102, the dummy gate structure 302, and the gate spacers 402. The spacer layer (and thus inner spacers 702) includes a material that is different than a material of the semiconductor layers 108 and a material of the gate spacers 402 to achieve desired etching selectivity during the etching process. In some embodiments, the inner spacers 702 include a dielectric material that includes silicon, oxygen, carbon, nitrogen, other suitable material, or combinations thereof (for example, silicon oxide (SiO₂), silicon oxynitride (SiON), silicon oxycarbide (SiOC), silicon oxycarbon nitride (SiOCN)). In some embodiments, the inner spacers 702 include a low-k dielectric material, such as those described herein.

Referring to FIGS. 1I-1 to 1I-3, source/drain features 802-1 and 802-2 (may be collectively referred to as source/drain features 802) are formed in the source/drain trenches 504A and 504B, so that the source/drain features 802-1 and 802-2 pass through the semiconductor layers 108 and are in the fins 112. The source/drain features are also formed on opposite sides of the dummy gate structures 302 in the X-direction. For example, the source/drain features 802-1 and 802-2 are formed on opposite sides of the dummy gate structure 302-1 in the X-direction, as shown in FIG. 1I-2. The source/drain features 802-1 and 802-2 are connected to and in contact with the semiconductor layers 108. In some aspects, the semiconductor layers 108 serve as channels to connect one source/drain feature 802-1 to another source/drain feature 802-2. Therefore, the semiconductor layers 108 may also be referred to as channels, channel layers, or channel members. In some embodiments, the source/drain features 802-1 and 802-2 may have top surfaces that extend higher than top surfaces of the topmost semiconductor layers 108 (e.g., in the Z-direction), as shown in FIG. 1I-2. In other embodiments, the top surfaces of the source/drain features 802-1 and 802-2 are substantially level with the top surfaces of the topmost semiconductor layers 108 (i.e., substantially coplanar). As discussed above, the bottom surfaces of the source/drain trenches 504A are lower than the bottom surfaces of the source/drain trenches 504B. Therefore, bottom surfaces of the source/drain features 802-1 are lower than bottom surfaces of the source/drain features 802-2. In some aspects, a depth/thickness of the source/drain features 802-1 is greater than a depth/thickness of the source/drain features 802-2. In some embodiments, in the Y-Z cross-sectional view shown in FIG. 1I-2, the source/drain features 802-1 and 802-2 may have the top surfaces that extend higher than top surfaces of the gate spacers 402 (e.g., in the Z-direction).

One or more epitaxy processes may be employed to grow the source/drain features 802-1 and 802-2. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 802 may include any suitable semiconductor materials. For example, the source/drain features 802 for n-type GAA transistors may include silicon (Si), silicon carbide (SiC), silicon phosphide (SiP), silicon arsenide (SiAs), silicon phosphoric carbide (SiPC), or combinations thereof; while the source/drain features 802 for p-type GAA transistors may include silicon (Si), silicon germanium (SiGe), germanium (Ge), silicon germanium carbide (SiGeC), or combinations thereof. The source/drain features 802-1 and 802-2 may be doped in-situ or ex-situ. For example, the epitaxially grown Si source/drain features may be doped with carbon to form silicon:carbon (Si:C) source/drain features, phosphorous to form silicon:phosphor (Si:P) source/drain features, or both carbon and phosphorous to form silicon carbon phosphor (SiCP) source/drain features; and the epitaxially grown SiGe source/drain features may be doped with boron. The source/drain features 802-1 and 802-2 may also be referred to as source/drain, or source/drain regions. In some embodiments, source/drain feature(s) 802 may refer to a source or a drain, individually or collectively dependent upon the context. In some embodiments, the source/drain features 802 for n-type transistors may be referred to as n-type source/drain features and the source/drain features 802 for p-type transistors may be referred to as p-type source/drain features. One or more annealing processes may be performed to activate the dopants in the source/drain features 802-1 and 802-2. The annealing processes may include rapid thermal annealing (RTA) and/or laser annealing processes.

Referring to FIGS. 1J-1 to 1J-3, a contact etch stop layer (CESL) 1002 over the source/drain features 802-1 and 802-2 and an interlayer dielectric (ILD) layer 1004 over the CESL 1002 are formed to fill the space between the gate spacers 402 and in the source/drain trenches 504A and 504B. Specifically, the CESL 1002 is conformally formed on the sidewalls of the gate spacers 402 and the source/drain features 802-1 and 802-2, over the top surfaces of the source/drain features 802-1 and 802-2 and the top surfaces of the isolation structure 202, as shown in FIGS. 1J-1 and 1J-2

The ILD layer 1004 is formed over and between the CESL 1002 to fill a remaining space between the CESL 1002, between the gate spacers 402 and in the source/drain trenches 504A and 504B. The CESL 1002 includes a material that is different than ILD layer 1004. The CESL 1002 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layer 1004 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD 1004 may be formed by PECVD (plasma enhanced CVD), FCVD (flowable CVD), or other suitable methods.

Subsequent to the deposition of the CESL 1002 and the ILD layer 1004, a CMP process and/or other planarization process is performed on the CESL 1002, the ILD layer 1004, the gate spacers 402, and the hard mask layers 308 until the top surfaces of the dummy gate electrodes 306 are exposed. In some embodiments, portions of the dummy gate electrodes 306 are removed after the planarization process. In some embodiments, the ILD layer 1004 is recessed to a level below the top surface of the dummy gate electrode 306, and then an ILD protection layer is formed over the ILD layer 1004 to protect the ILD layer 1004 from subsequent etching processes. As such, the ILD layer 1004 is surrounded by the CESL 1002 and the ILD protection layer. In some embodiments, the ILD protection layer includes a material that is the same as or similar to that in the CESL 1002. In some other embodiments, the ILD protection layer includes a dielectric material such as Si₃N₄, SiCN, SiOCN, SiOC, a metal oxide such as HrO₂, ZrO₂, hafnium aluminum oxide, hafnium silicate, or other suitable material, and may be formed by CVD, PVD, ALD, or other suitable methods.

Referring to FIGS. 1K-1 to 1K-3, the dummy gate structures 302 are selectively removed through any suitable lithography and etching processes to form gate trenches 1102 (including gate trenches 1102-1 to 1102-3). In some embodiments, the lithography process may include forming a photoresist layer (resist), exposing the resist to a pattern, performing a post-exposure bake process, and developing the resist to form a masking element, which exposes a region including the dummy gate structures 302. Then, the dummy gate structures 302 are selectively etched through the masking element. The gate spacers 402 may be used as the masking element or a part thereof. Etch selectivity may be achieved by selecting the appropriate etching chemicals, and the dummy gate electrode 306 may be removed without substantially affecting the CESL 1002 and the ILD layer 1004. The removal of the dummy gate structures 302 creates the gate trenches 1102-1 to 1102-3, in which the gate trenches 1102-1 to 1102-3 expose the top surfaces of the fins 112 (specifically, the top surfaces of the topmost semiconductor layers 108) and the isolation structure 202.

Still referring to FIGS. 1K-1 to 1K-3, the semiconductor layers 106 of the fins 112 are selectively removed through the gate trenches 1102, using a wet or dry etching process for example, so that the semiconductor layers 108 are exposed in the gate trenches 1102 to form nanostructures stacked over each other, which serving as channels, channel layers, or channel members for resultant transistors. As such, the semiconductor layers 108 may be referred to as nanostructures. Specifically, the semiconductor layers 108 are stacked over each other in the Z-direction. Such a process may also be referred to as a release process, a channel release process, a wire release process, a nanowire release process, a nanosheet release process, a nanowire formation process, a nanosheet formation process, or a wire formation process. In some embodiments, the removal of the semiconductor layers 106 causes the exposed semiconductor layers 108 to be spaced apart from each other in the vertical direction (e.g., in the Z-direction). The exposed semiconductor layers 108 extend longitudinally in the horizontal direction (e.g., in the X-direction). Furthermore, each of the semiconductor layers 108 connects one source/drain feature 802-1 to another source/drain feature 802-2 (e.g., shown in FIG. 1K-1). In some embodiments, thicknesses of the semiconductor layers 108 exposed in the gate trenches 1102 may be reduced during the removal of the semiconductor layers 106. In other embodiments, heights of the base fins 102A and 102B in the gate trenches 1102 (e.g., shown in FIGS. 1K-1 and 1K-3) may also be reduced during the removal of the semiconductor layers 106. Furthermore, the thickness of the isolation structure 202 exposed in the gate trenches 1102 (e.g., shown in FIG. 1K-3) may also be reduced during the removal of the semiconductor layers 106.

Referring to FIGS. 1L-1 to 1L-3, gate structures 1208 (including gate structures 1208-1 to 1208-3) are formed in the gate trenches 1102 to wrap around the exposed semiconductor layers 108. As such, the gate structures 1208 replace the dummy gate structures 302. In some embodiments, the gate structures 1208 extend in the Y-direction, as shown in FIG. 1L-3. (see FIG. 1P-1). As shown in FIG. 1L-1, the source/drain features 802-1 and 802-2 are formed on opposite sides of the gate structure 1208-2 in the X-direction. The gate structures 1208 each includes gate dielectric layer 1204 and gate electrode 1206 (including gate electrodes 1206-1 and 1206-2) over the gate dielectric layer 1204. In some embodiments, the gate dielectric layers 1206 are formed to wrap around the semiconductor layers 108 in the gate trenches 1102. Additionally, the gate dielectric layers 1204 also formed on the sidewalls of the inner spacers 702 and the gate spacers 402 (shown in FIG. 1L-1), as well as over the top surfaces of the isolation structure 202 (shown in FIG. 1L-3). The gate dielectric layers 1204 may include a dielectric material having a dielectric constant greater than a dielectric constant of SiO₂, which is approximately 3.9. For example, the gate dielectric layers 1204 may include hafnium oxide (HfO₂), which has a dielectric constant in a range from about 18 to about 40. Alternatively, the gate dielectric layers 1204 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layers 1502 may be formed by ALD, PVD, CVD, oxidation, and/or other suitable methods.

In some embodiments, the gate structures 1208 each may further include interfacial layer 1202 formed to wrap around the exposed semiconductor layers 108 before the formation of the gate dielectric layers 1204, so that the gate dielectric layers 1204 are separated from semiconductor layers 108 by the interfacial layer. In some embodiments, the interfacial layer may include a dielectric material such as silicon oxide (SiO₂), HfSiO, or silicon oxynitride (SiON). The interfacial layer may be formed by chemical oxidation, thermal oxidation, ALD, CVD, and/or other suitable method.

The gate electrodes 1206 are formed to fill the remaining spaces of the gate trenches 1102, and over the gate dielectric layers 1204 in such a way that the gate electrodes 1206 wrap around the semiconductor layers 108, the gate dielectric layer 1204, and the interfacial layers 1202 (if present). The gate electrodes 1206 each may include a single layer or alternatively a multi-layer structure. In some embodiments, the gate electrodes 1206 each may include a capping layer, a barrier layer, work function metal layers, and a fill material. The gate electrodes 1206-1 and 1206-2 may have the same or different materials. In some embodiments, the gate electrodes 1206-1 and 1206-2 may have n-type work function metal layers for n-type transistors or p-type work function metal layers for p-type transistors. In other embodiments, the gate electrodes 1206-1 may have n-type/p-type work function metal layers and the gate electrodes 1206-1 may have p-type/n-type work function metal layers.

The n-type work function metal layer may be formed adjacent to the barrier layer. In an embodiment, the n-type work function metal layer is a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer.

The p-type work function metal layer may be formed adjacent to the n-type work function metal layer. In an embodiment, the p-type work function metal layer may be a material such as TiN, TaN, Ru, Mo, Al, WN, ZrSi2, MoSi2, TaSi2, NiSi2, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the p-type work function metal layer may be deposited using a deposition process such as ALD, CVD, or the like, although any suitable deposition process may be used.

Referring to FIGS. 1M-1 to 1M-3, a front-side interconnection structure is formed over the workpiece 100. The front-side interconnection structure includes a CESL 1302, an ILD layer 1304, a CESL 1306, an ILD layer 1308, a source/drain contact 1310, and vias 1312 and 1314. The CESL 1302 is formed over the gate structures 1208, the CESL 1002, and the ILD layer 1004, and the ILD layer 1304 is formed over the CESL 1302. The CESL 1306 is formed over the ILD layer 1304 and the ILD layer 1308 is formed over the CESL 1306. The CESLs 1302 and 1306 include a material similar to the material of the CESL 1002 discussed above. The ILD layers 1304 and 1308 include a material similar to the material of the ILD layer 1004 discussed above.

As shown in FIG. 1M-1, the source/drain contact 1310 is formed over the source/drain feature 802-2, and passing through the CESL 1302 and the ILD layer 1304. In some embodiments, a portion of the source/drain feature 802-2 is removed during the formation of the source/drain contact 1310. The source/drain contact 1310 is in contact with and electrically connected to (a top surface of) the source/drain feature 802-2. The formation of the source/drain contact 1310 may include forming a contact opening passing through the CESL 1302, the ILD layer 1304, the CESL 1002, and the ILD layer 1004, and exposing the source/drain feature 802-2, and depositing a conductive material in the contact opening, after the formation of the CESL 1302 and the ILD layer 1304, and before the formation of the CESL 1306 and the ILD layer 1308. The conductive material of the source/drain contact 1310 may include Al, Cu, W, Co, Ti, Ta, Ru, Rh, Ir, Pt, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contact 1310 may include single conductive material layer or multiple conductive layers.

The via 1312 is formed passing through the CESL 1306 and the ILD layer 1308, and is electrically connected to the source/drain contact 1310. The vias 1314 are formed passing through the CESL 1302, the ILD layer 1304, the CESL 1306, and the ILD layer 1308, and is electrically connected to the gate structures 1208, as shown in FIG. 1M-3. In some embodiments, the vias 1314 electrically connected to the gate structures 1208 may be referred to as gate vias. The materials of the vias 1312 and 1314 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof. It should be noted that there may be more CESLs, ILD layers in the front-side interconnection structure, and vias and metal lines or conductors therein to form desired circuit routing.

After the formation of the front-side interconnection structure, the workpiece 100 may be flipped to form a back-side interconnection structure. For the purpose of simplicity, the sequent figures are shown without being flipped. Referring to FIGS. 1N-1 to 1N-3, a portion of the substrate 102 is removed (specifically, be thinned) by performing a CMP process and/or other planarization process. As shown in FIGS. 1N-2 and 1N-3, bottom surfaces of the isolation structure 202 are exposed after the CMP process. In some embodiments, portions of the isolation structure 202 may be removed (specifically, be thinned) during the CMP process.

Referring to FIGS. 1M-1 to 1M-3, portions of the substrate 102 (which directly under the source/drain features 802-1) and the source/drain features 802-1 are recessed by performing one or more lithography and etching processes on bottom surfaces of the substrate 102 (or on back-side of the substrate 102) to form openings 1402. The openings 1402 are respectively under the source/drain features 802-1. In some embodiments, the openings 1402 may be referred to as contact openings or source/drain contact openings. As shown in FIGS. 1O-1 and 1O-2, the openings 1402 expose the bottom surfaces of the source/drain features 802-1 for subsequent back-side via formation. Furthermore, the bottom surfaces of the source/drain features 802-1 are still lower than the bottom surfaces of the source/drain features 802-2.

Referring to FIGS. 1P-1 to 1P-4, a conductive material is form to fill the openings 1402 to respectively form vias 1502. FIG. 1P-1 is a top view (or a layout) of the workpiece 100 at a fabrication stage, in accordance with some embodiments of the present disclosure. FIG. 1P-2 is an X-Z cross-sectional view of the workpiece 100 at the fabrication stages along a line A-A′ of FIG. 1P-1, in accordance with some embodiments of the present disclosure. FIG. 1P-3 is a Y-Z cross-sectional view of the workpiece 100 at various fabrication stages along a line B-B′ of FIG. 1P-1, in accordance with some embodiments of the present disclosure. FIG. 1P-4 is a Y-Z cross-sectional view of the workpiece 100 at various fabrication stages along a line C-C′ of FIG. 1P-1, in accordance with some embodiments of the present disclosure.

As shown in FIGS. 1P-2 and 1P-3, the vias 1502 are in contact with and electrically connected to the bottom surfaces of the source/drain features 802-1. The vias 1502 include a material similar to the material of the ILD layer 1004 discussed above. As discussed above, the bottom surfaces of the source/drain features 802-1 are lower than the bottom surfaces of the source/drain features 802-2. In other words, the depth/thickness of the source/drain features 802-1 is greater than the depth/thickness of the source/drain features 802-2. As shown in FIG. 1P-2, a thickness T1 of the source/drain features 802-1 in the Z-direction is in a range from about 40 nm to about 120 nm, and a thickness T2 of the source/drain features 802-2 in the Z-direction is in a range from about 20 nm to about 80 nm. A width of the source/drain features 802-1 and 802-2 in the X-direction is in a range from about 6 nm to about 200 nm. In some embodiments, a distance D from the bottom surface of the source/drain feature 802-1 to the bottom surface of the source/drain feature 802-2 in the Z-direction is in a range from about 10 nm to about 50 nm. In some embodiments, the vias 1502 are square in a top view, as shown in FIG. 1P-1. Therefore, a width of the vias 1502 in the X-direction and a length of the vias 1502 in the Y-direction are the same. Because of greater depth or greater thickness of the source/drain feature 802-1, the vias 1502 may be formed to have sheet structure. Therefore, a width of the vias 1502 in the X-direction is greater than a thickness of the vias 1502 in the Z-direction. In other words, a ratio of the width of the vias 1502 in the X-direction to the thickness of the vias 1502 in the Z-direction is greater than 1. Therefore, the vias 1502 may be referred to as sheet vias and back-side sheet vias. In some embodiments, the thickness of the vias 1502 is in a range from about 8 nm to about 100 nm. The width/length of the vias 1502 is in a range from about 6 nm to about 200 nm. In some embodiments, the width of the vias 1502 in the X-direction and the width of the source/drain features 802-1 in the X-direction are the same, as shown in FIG. 1P-2. In other embodiments, the length of the vias 1502 in the Y-direction and a length of active areas 1504-1 and 1504-2 (each including channel regions having the semiconductor layers 108 and the source/drain features 802-1 and 802-2) are the same in the Y-direction, as shown in FIG. 1P-1.

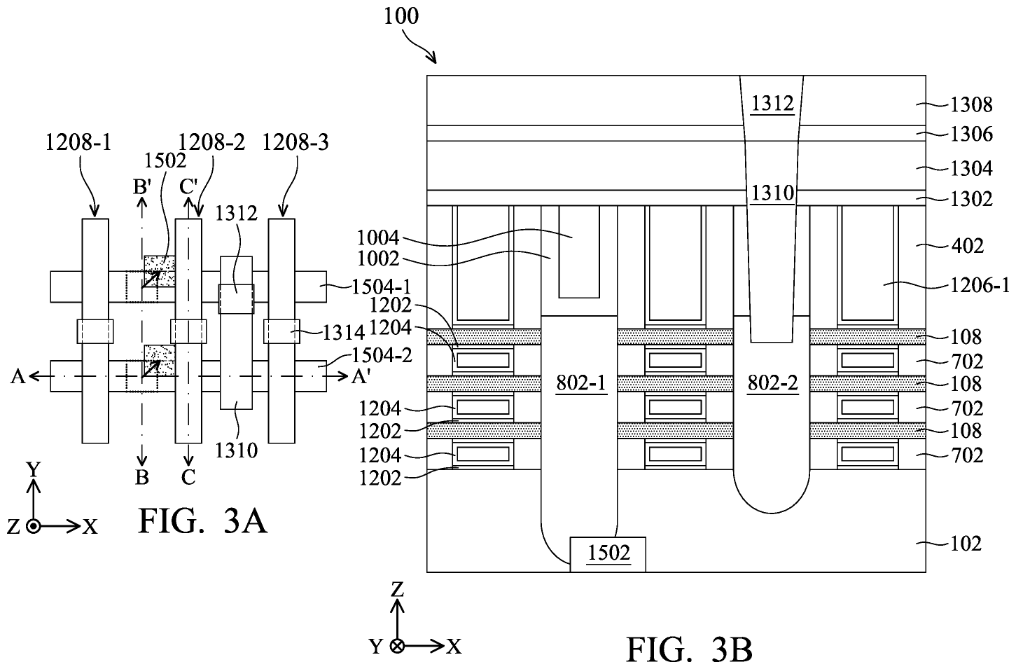

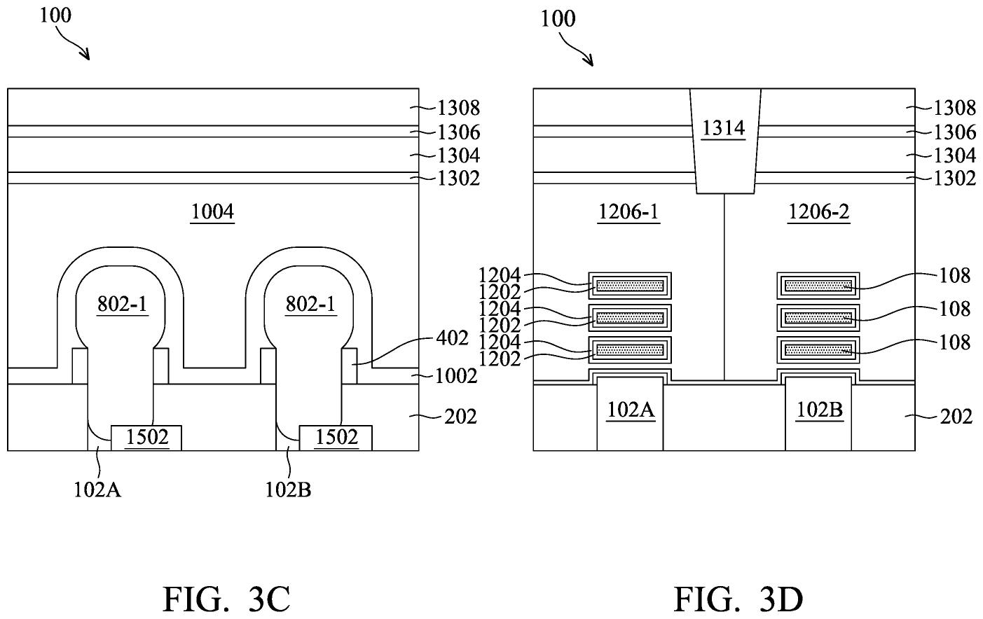

FIGS. 3A to 5A are top views (or layouts) of the workpiece 100 at a fabrication stage, in accordance with some alternative embodiments of the present disclosure. FIGS. 3B to 5B are X-Z cross-sectional views of the workpiece 100 at the fabrication stages along lines A-A′ of FIGS. 3A to 5A, respectively, in accordance with some alternative embodiments of the present disclosure. FIGS. 3C to 5C are Y-Z cross-sectional views of the workpiece 100 at various fabrication stages along lines B-B′ of FIGS. 3A to 5A, respectively, in accordance with some alternative embodiments of the present disclosure. FIGS. 3D to 5D are Y-Z cross-sectional views of the workpiece 100 at various fabrication stages along lines C-C′ of FIGS. 3A to 5A, respectively, in accordance with some alternative embodiments of the present disclosure.

As discussed above, due to process variation, the vias 1502 may be formed to be shifted from the desired position. Specifically, during the formation of the openings 1402, the openings 1402 shift due to process variation, such that portions of the substrate 102, the isolation structure 202, and the source/drain features 802-1 are removed, thereby causing the vias 1502 formed in the openings 1402 are also shifted from the desired position. As shown in FIGS. 3A to 3C, the vias 1502 shift in the X-direction and the Y-direction. In some embodiments, the vias 1502 shift and extend directly under the gate spacers 402 and the inner spacers 702 in the Z-direction. In some embodiments, the source/drain features 802-1 are in contact with sidewalls of the vias 1502, as shown in FIGS. 3B and 3C. Furthermore, top surfaces of the vias 1502 are in contact with the isolation structure 202. Therefore, because of the greater depth and the greater thickness of the source/drain feature 802-1 and the sheet structure of the vias 1502, even though the vias 1502 shift from the desired position due to process variation, the vias 1502 are still separated from the gate structures 1208 without being in contact with the gate structures 1208, thereby avoiding short-circuits between the back-side vias and gate structures to cause the failure of GAA transistors. As such, the sheet structure of the vias 1502 increases the process window and yield.

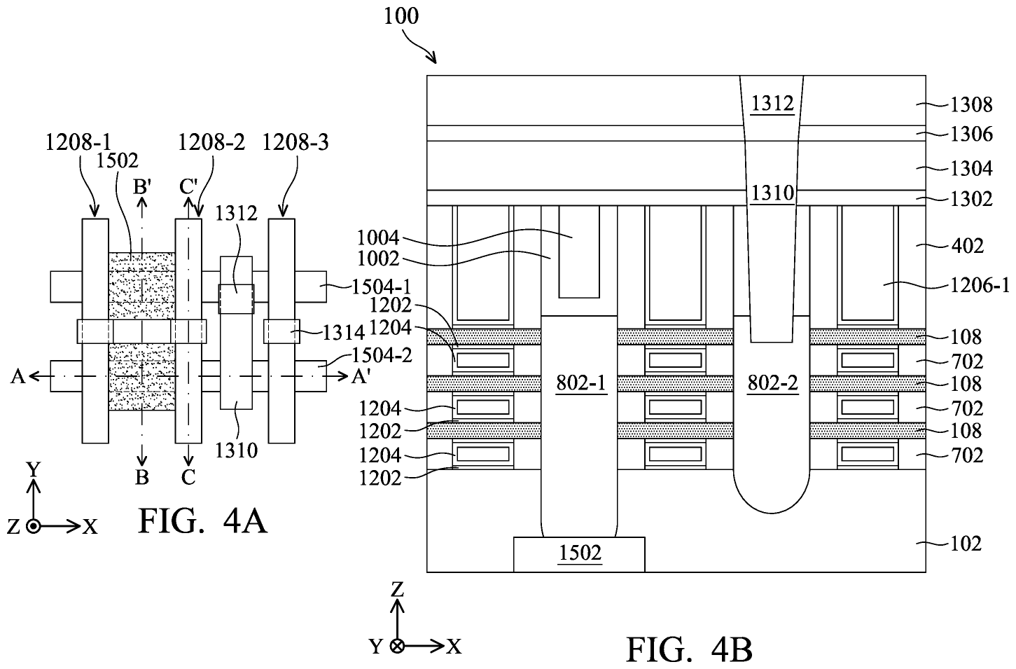

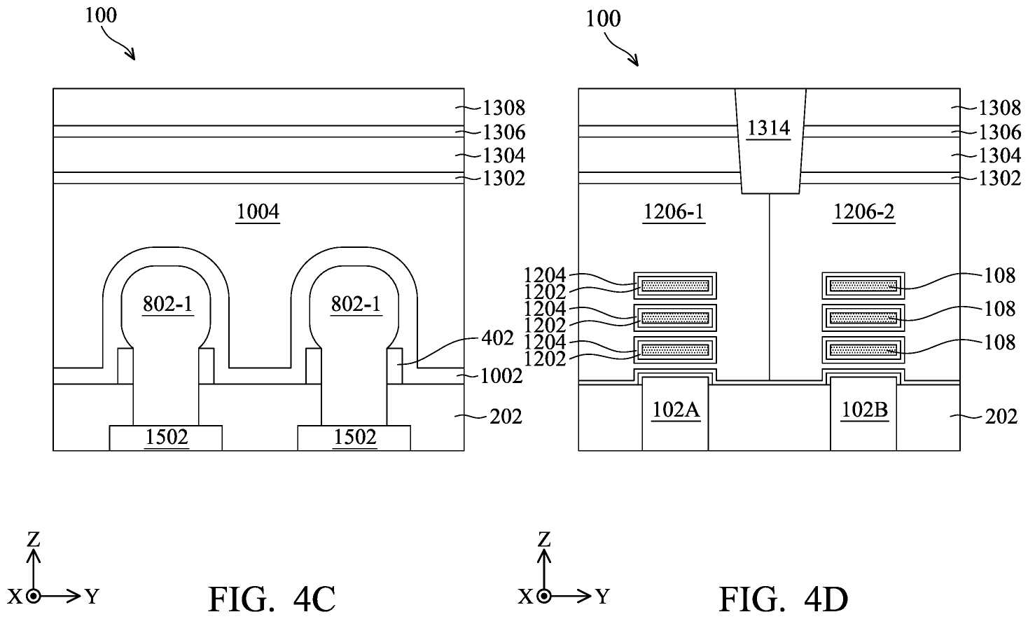

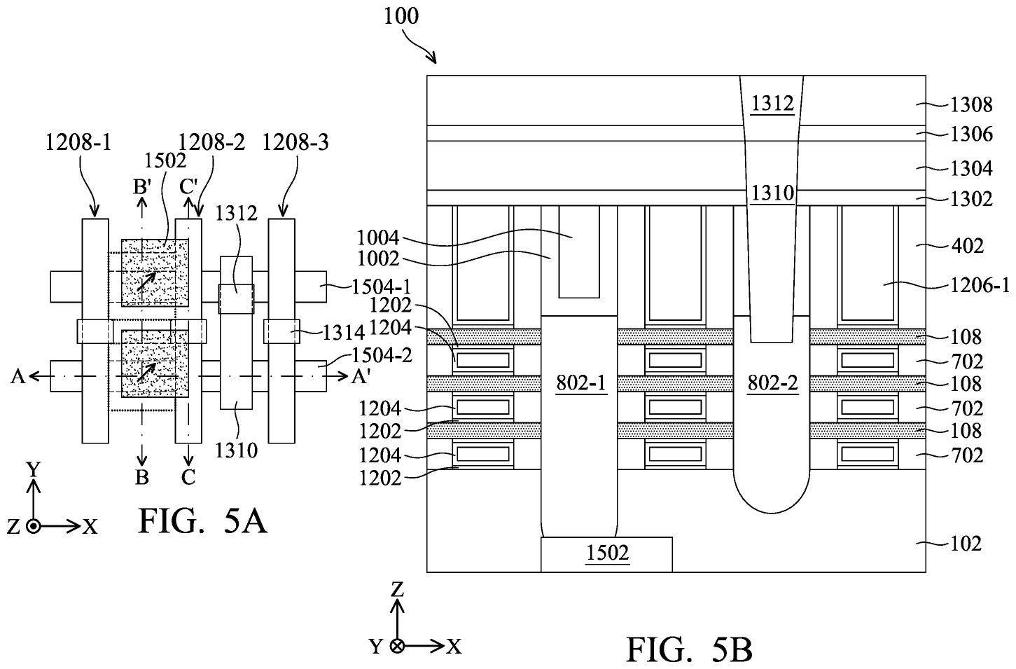

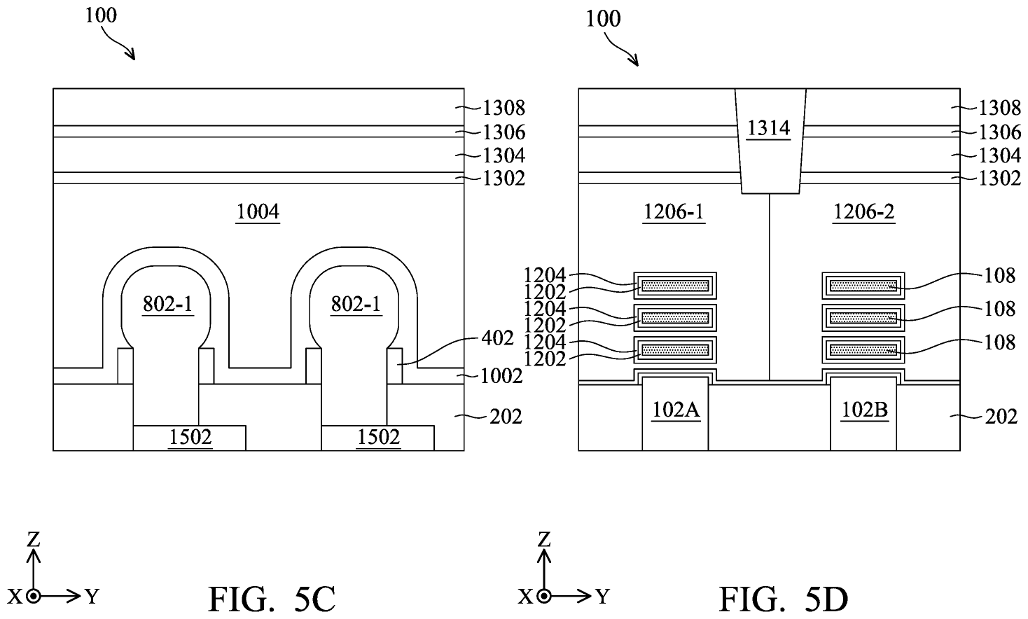

As shown in FIGS. 4A to 4B, the vias 1502 may be formed and designed with larger width and length (i.e., larger area in the top view). In some embodiments, the width of the vias 1502 in the X-direction is greater than the width of the source/drain features 802-1 in the X-direction, as shown in FIG. 4C. In other embodiments, the length of the vias 1502 in the Y-direction is greater than the length of the active areas 1504-1 and 1504-2 in the Y-direction (a length of the source/drain features 802-1 and 802-2 in the Y-direction), as shown in FIGS. 4A and 4C. Such larger-area vias 1502 may result in a larger shift tolerance for process variation. As shown in FIGS. 5A to 5D, the vias 1502 shift and extend directly under the gate structure 1208-2 in the Z-direction. Therefore, the larger-area vias 1502 further increases the process window and decreases resistance, so that the performance of the GAA transistors are improved.

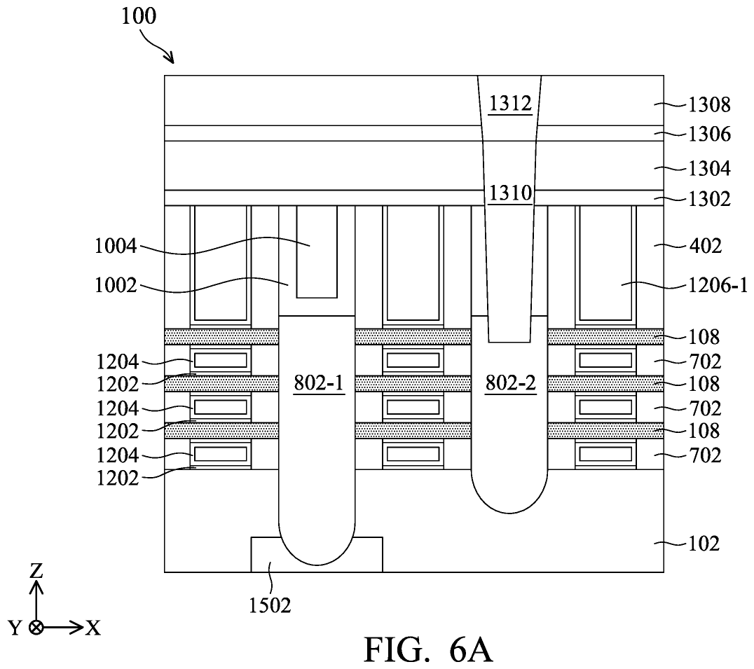

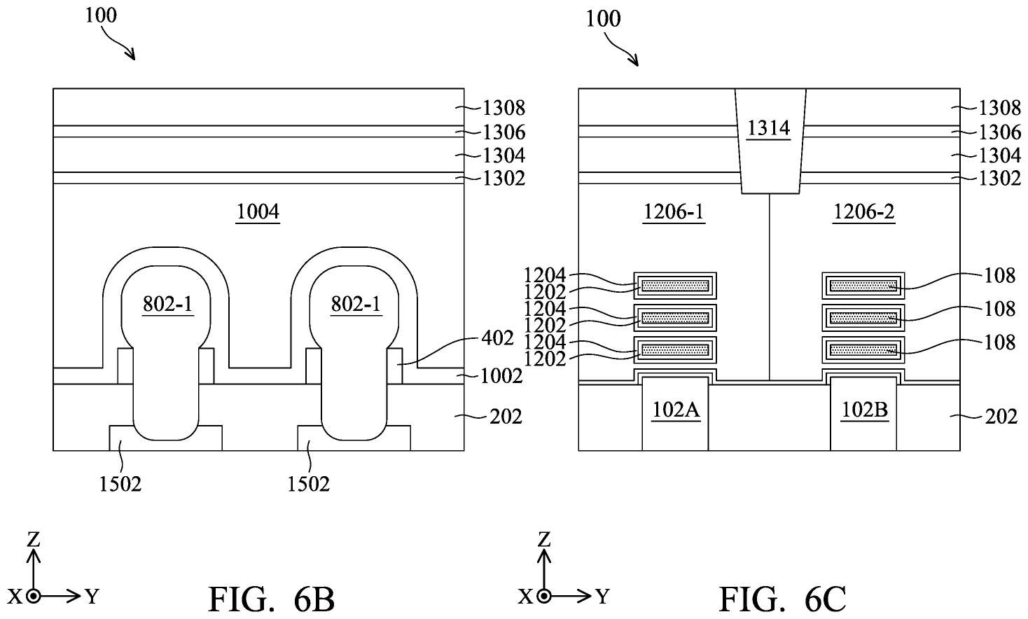

FIGS. 6A to 16A are X-Z cross-sectional views of the workpiece 100 at the fabrication stages along lines A-A′ of FIGS. 1B, 1P-1, or 3A to 5A, in accordance with some alternative embodiments of the present disclosure. FIGS. 6B to 16B are Y-Z cross-sectional views of the workpiece 100 at various fabrication stages along lines B-B′ of FIGS. 1B, 1P-1, or 3A to 5A, in accordance with some alternative embodiments of the present disclosure. FIGS. 6C to 16C are Y-Z cross-sectional views of the workpiece 100 at various fabrication stages along lines C-C′ of FIGS. 1B, 1P-1, or 3A to 5A, in accordance with some alternative embodiments of the present disclosure.

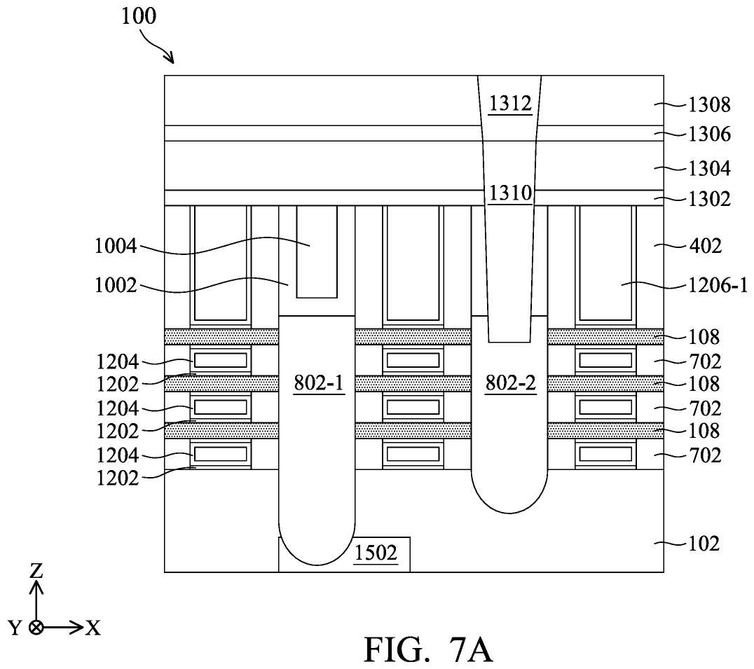

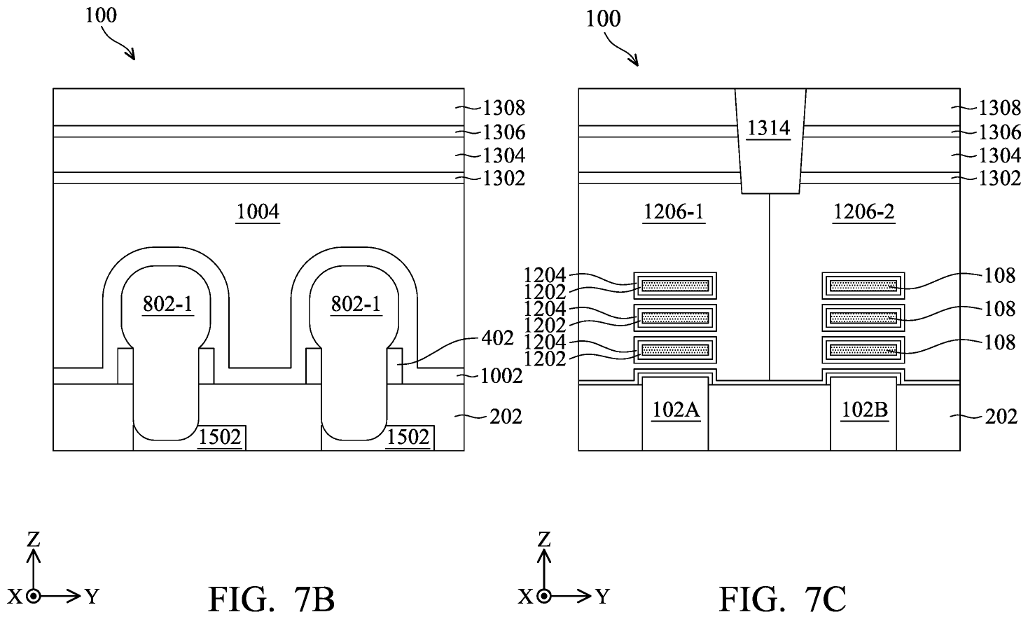

As discussed above, the portions of the source/drain features 802-1 are removed during the formation of the vias 1502. Therefore, the source/drain features 802-1 have substantially flat bottom surfaces, so that the vias 1502 have substantially flat top surfaces, as shown in FIGS. 1P-2, 1P-3, 4B, 4C, 5B, and 5C. In some embodiments, the selective etching process is performed to form the openings 1402 for the vias 1502, with minimal (or no) etching of the source/drain features 802-1, so that the bottom surfaces of the source/drain features 802-1 remain nonplanar, as shown in FIGS. 6A to 6C. In some aspects, the source/drain features 802-1 have convex bottom surfaces. As such, the vias 1502 have concave top surfaces in contact with the convex bottom surfaces of the source/drain features 802-1. This increases contact area between the source/drain features 802-1 and the vias 1502, so that contact resistance is decreased, thereby improving the performance of the GAA transistors. As shown in FIGS. 7A to 7C, the vias 1502 with the concave top surfaces shift and extend directly under the gate structure 1208-2 in the Z-direction.

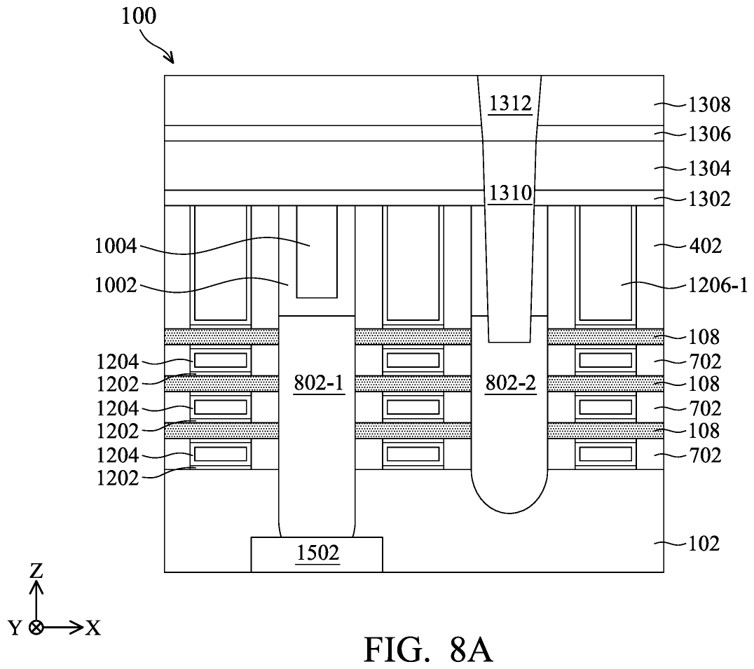

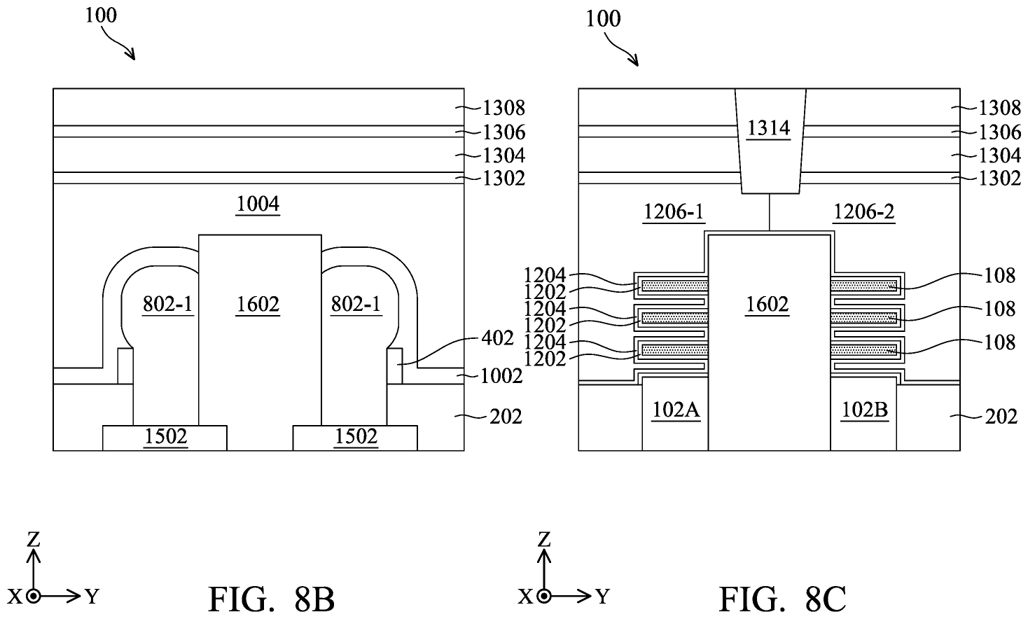

As shown in FIGS. 8A to 8C, a dielectric layer 1602 is formed between the source/drain features 802-1 and 802-2, and between the semiconductor layers 108. Specifically, the dielectric layer 1602 is between and in contact with sidewalls of the source/drain features 802-1, as shown in FIG. 8B. The dielectric layer 1602 is further between and in contact with sidewalls of the semiconductor layers 108, as shown in FIG. 8C. It should be noted that the dielectric layer 1602 is also between and in contact with sidewalls of the source/drain features 802-2. In some embodiments, the gate dielectric layer 1204 wraps around the dielectric layer 1602. In some aspects, as shown in FIG. 8C, the gate dielectric layer 1204 are formed on a top surface and sidewalls of the dielectric layer 1602. The transistors shown in FIGS. 8A to 8C may be referred to as forksheet transistors.

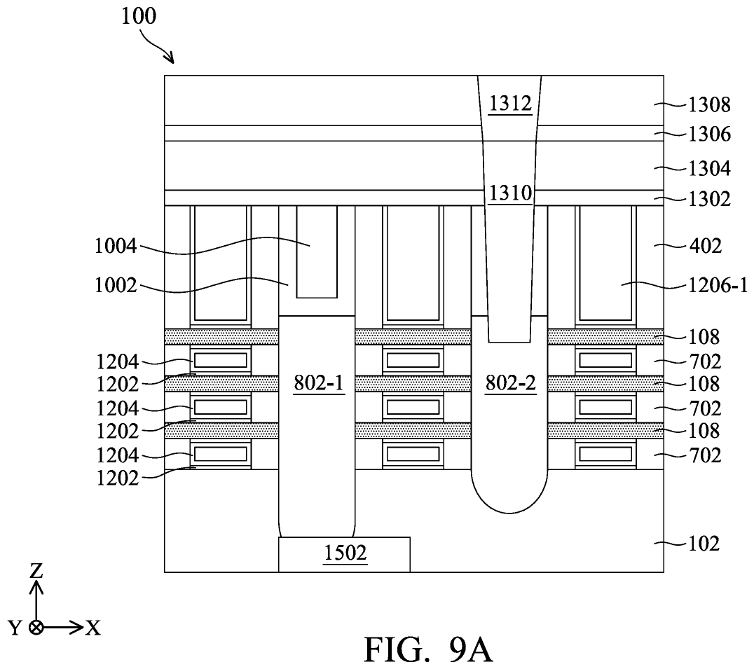

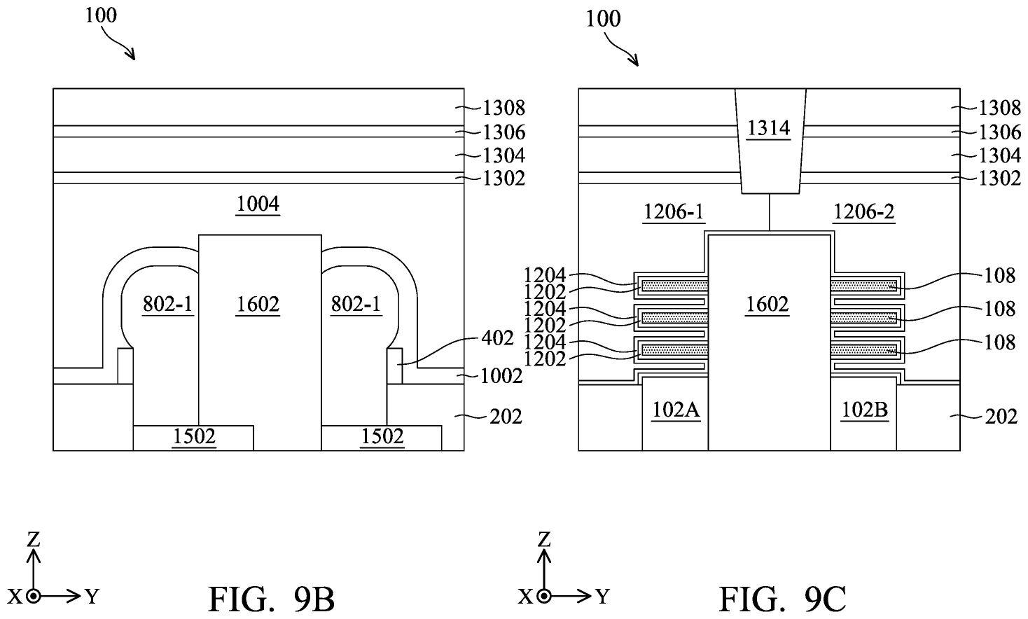

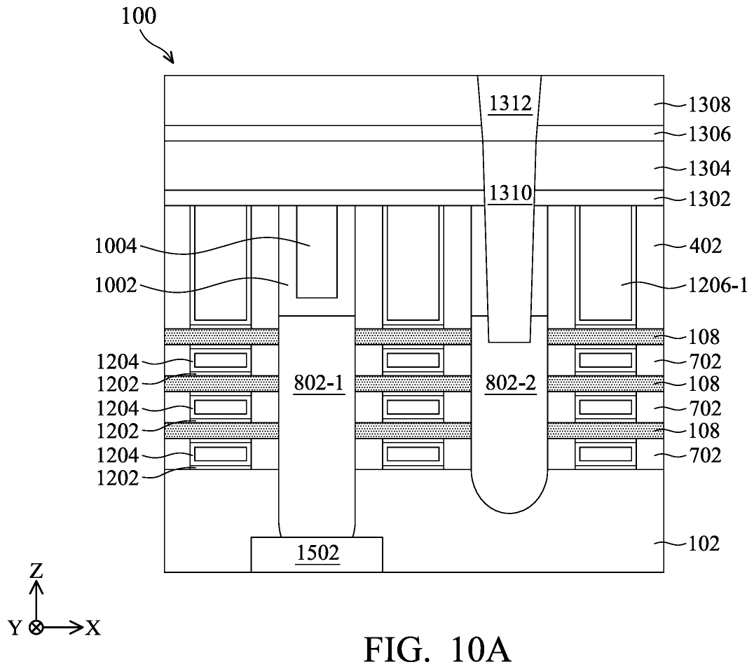

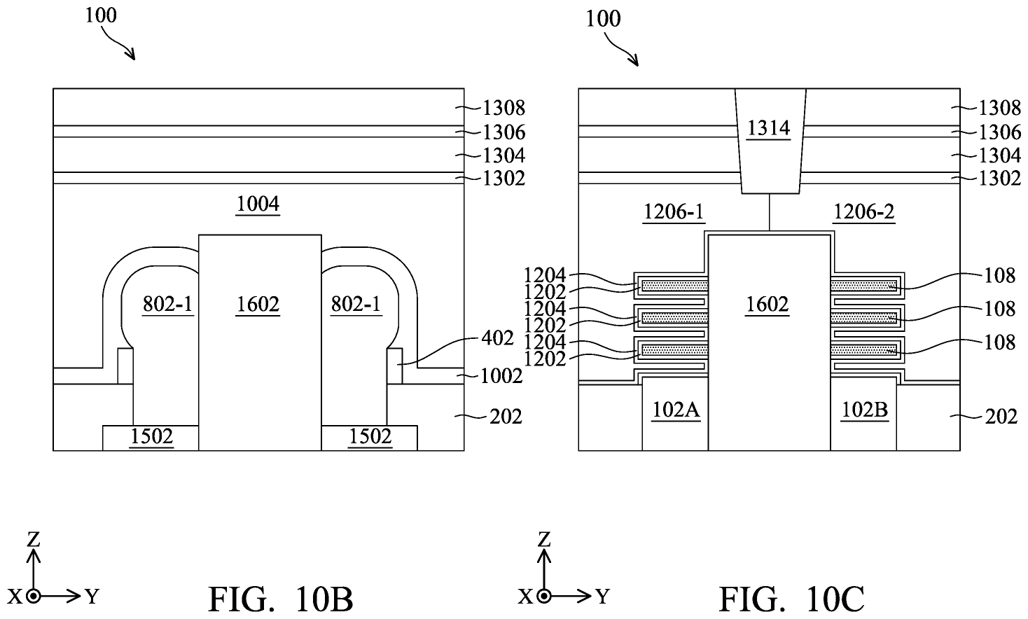

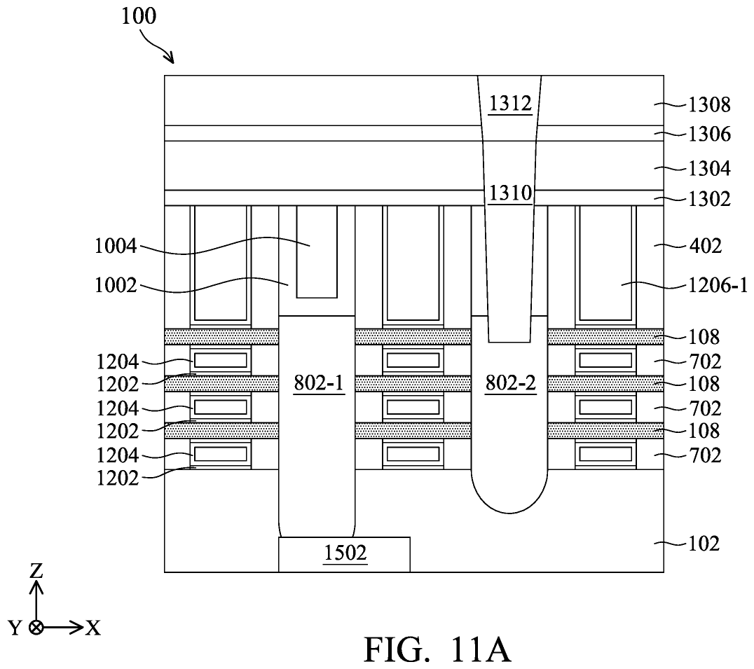

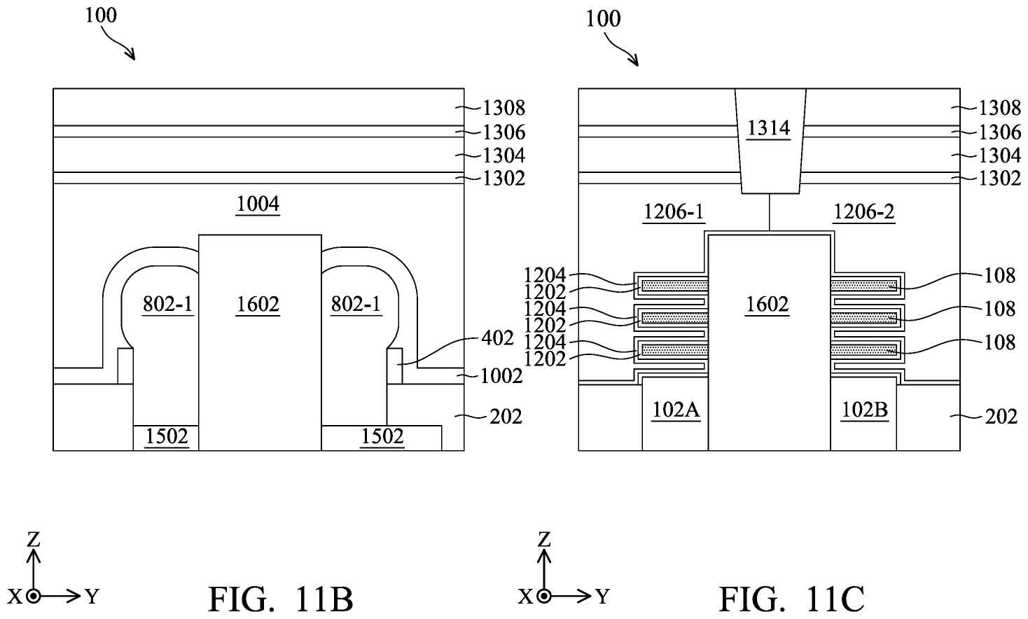

During the formation of the vias 1502 in FIGS. 8A to 8C, portions of the substrate 102, the isolation structure 202, the source/drain features 802-1, and the dielectric layer 1602 are removed. As such, the dielectric layer 1602 is non-rectangular in the Y-Z cross-sectional view shown in FIG. 8B. Furthermore, the dielectric layer 1602 is in contact with the top surfaces and the sidewalls of the vias 1502, as shown in FIG. 8B. As shown in FIGS. 9A to 9C, the vias 1502 shift and extend directly under the gate structure 1208-2 in the Z-direction. The dielectric layer 1602 in the Y-Z cross-sectional view shown in FIG. 9B is asymmetric about a Z-axis (parallel to the Z-direction). In some embodiments, the selective etching process is performed to form the openings 1402 for the vias 1502, with minimal (or no) etching of the dielectric layer 1602. As such, referring to FIGS. 10A to 10C, the dielectric layer 1602 is rectangular. As shown in FIGS. 11A to 11C, the vias 1502 shift and extend directly under the gate structure 1208-2 in the Z-direction without the dielectric layer 1602 is etched during the formation of the vias 1502. As shown in FIG. 111B, the vias 1502 may have different lengths in the Y-direction.

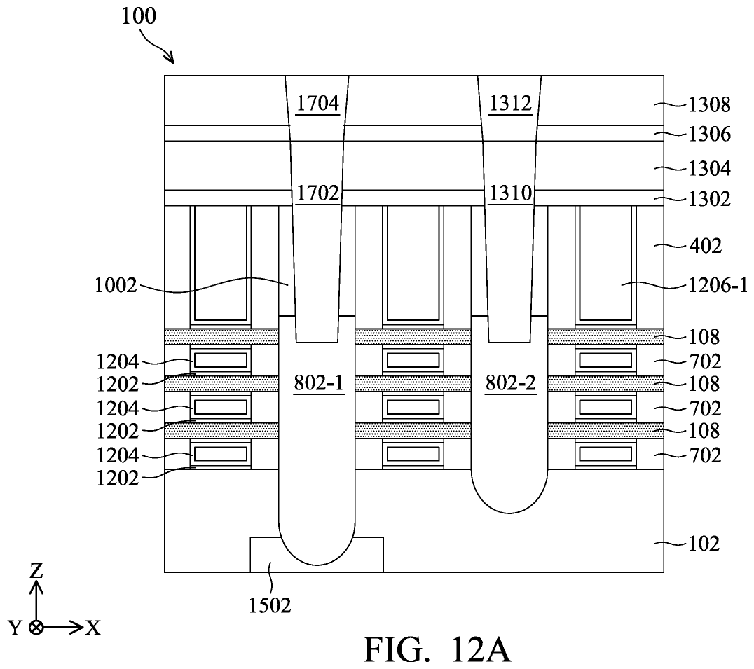

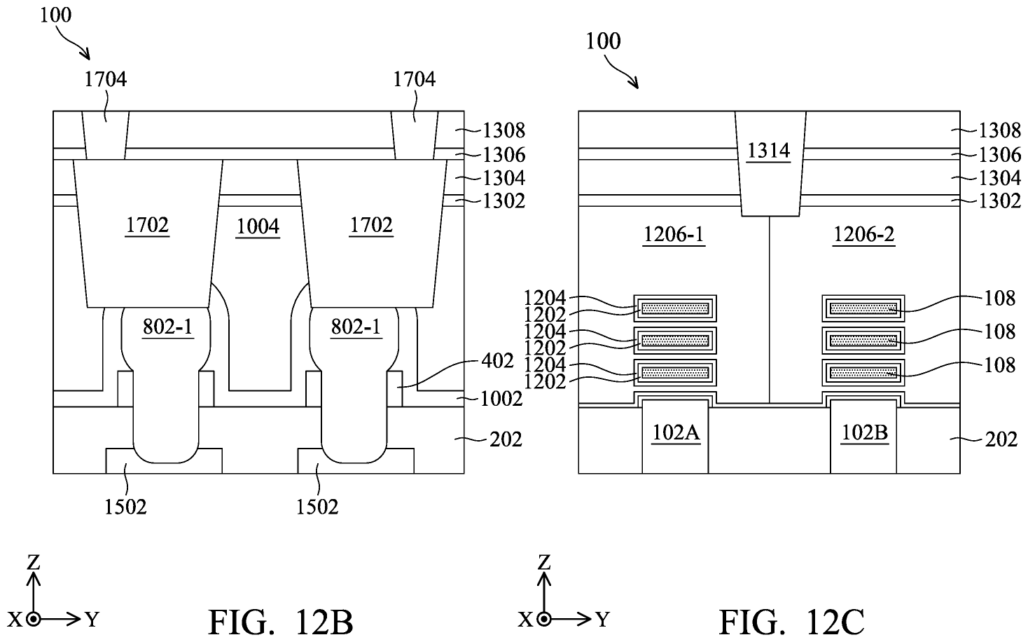

In some embodiments, referring to FIGS. 12A to 12C, the source/drain contacts 1702 are respectively formed over the source/drain features 802-1, and passing through the CESL 1302, the ILD layer 1304, the CESL 1002, and the ILD layer 1004. The source/drain contacts 1702 are in contact with and electrically connected to (top surfaces of) the source/drain feature 802-1. Furthermore, vias 1704 are formed passing through the CESL 1306 and the ILD layer 1308, and are electrically connected to the source/drain contacts 1702. Because the deeper and larger depth source/drain features 802-1 each has the via 1502 and the source/drain contact (and the via 1704) for both side (front-side and back-side) metal routings, the resistance are further decreased, thereby improving the performance of the GAA transistors.

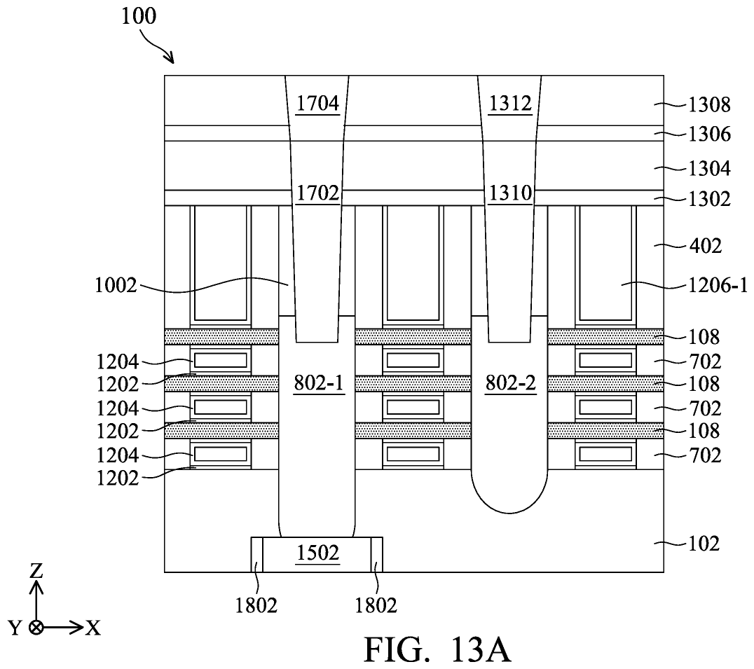

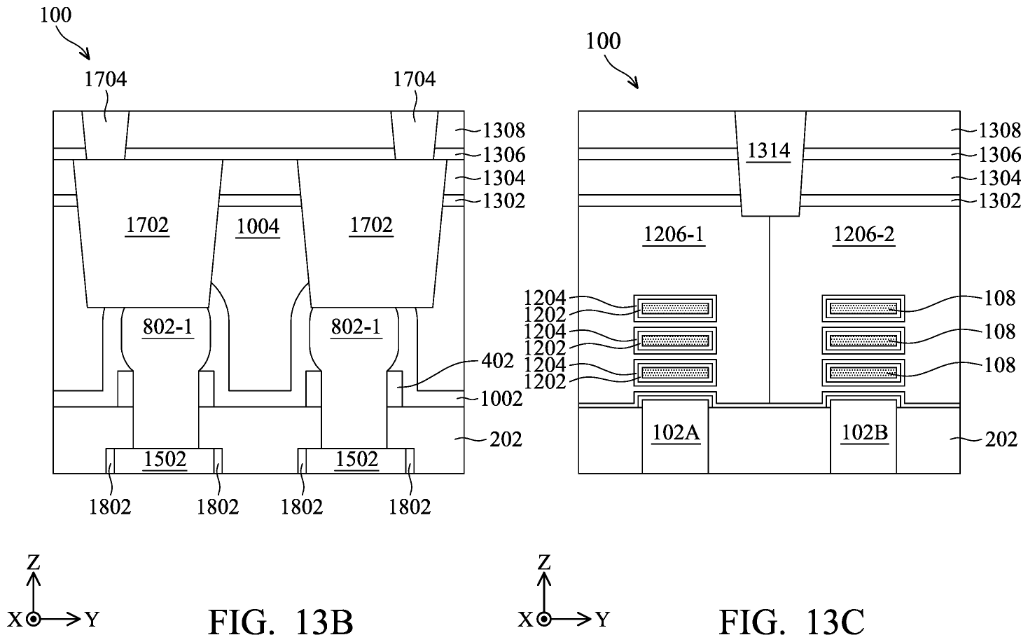

In some embodiments, referring to FIGS. 13A to 13C, before forming the conductive material in the openings 1402 for forming the vias 1502, a dielectric layer 1802 is formed on sidewalls of the openings 1402, and then the conductive material is formed in the openings 1402 to form the vias 1502 with the dielectric layer 1802 on its sidewalls. The dielectric layer 1802 further enhances the isolation of the vias 1502 from other conductive features, such as gate structures 1208 and the source/drain features 802-2. the dielectric layer 1802 includes a dielectric material nitride, such as Si₃N₄, SiO₂, SiC, SiOC, SiON, SiCN, SiOCN, carbon doped oxide, nitrogen doped oxide, porous oxide, or combinations thereof.

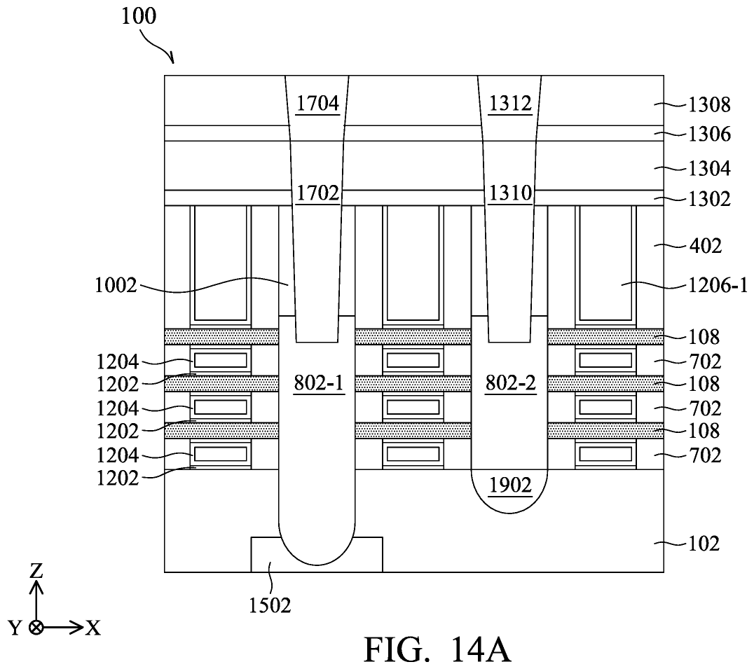

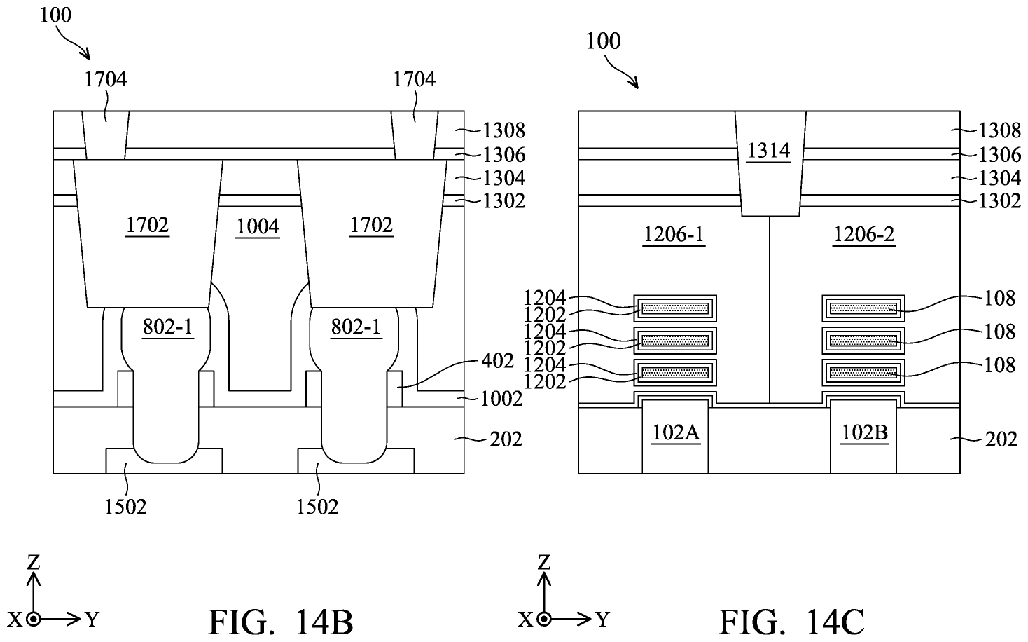

In some embodiments, referring to FIGS. 14A to 14C, dielectric layers 1902 are formed directly under and in contact with the source/drain features 802-2 in the Z-direction. The dielectric layers 1902 have substantially flat top surfaces in contact with the source/drain features 802-2. Therefore, the source/drain features 802-2 have the substantially flat bottom surfaces, as shown in FIG. 14A. Further, the dielectric layers 1902 have convex bottom surfaces. The dielectric layer 1902 further enhances the isolation of the source/drain features 802-2 from the gate structures 1208 and the the source/drain features 802-1. The dielectric layers 1902 include a dielectric material nitride, such as Si3N4, SiO2, SiC, SiOC, SiON, SiCN, SiOCN, carbon doped oxide, nitrogen doped oxide, porous oxide, or combinations thereof.

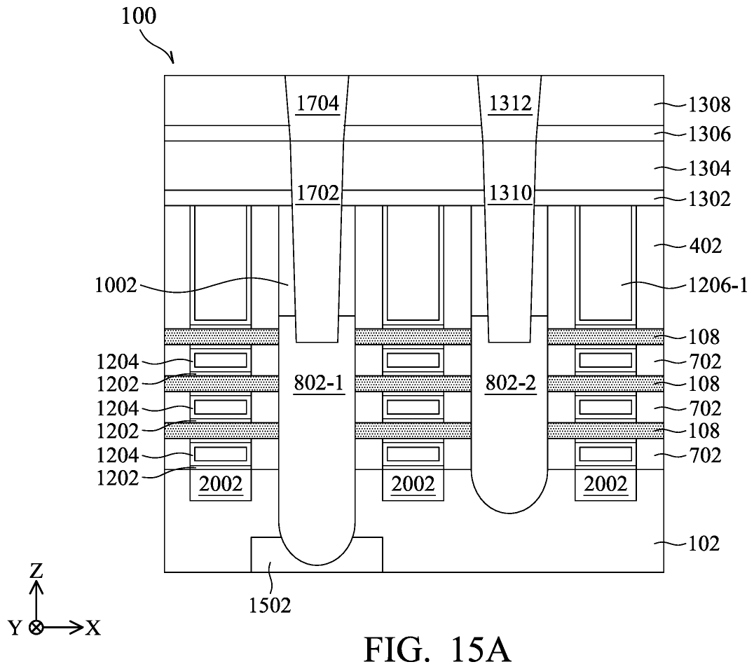

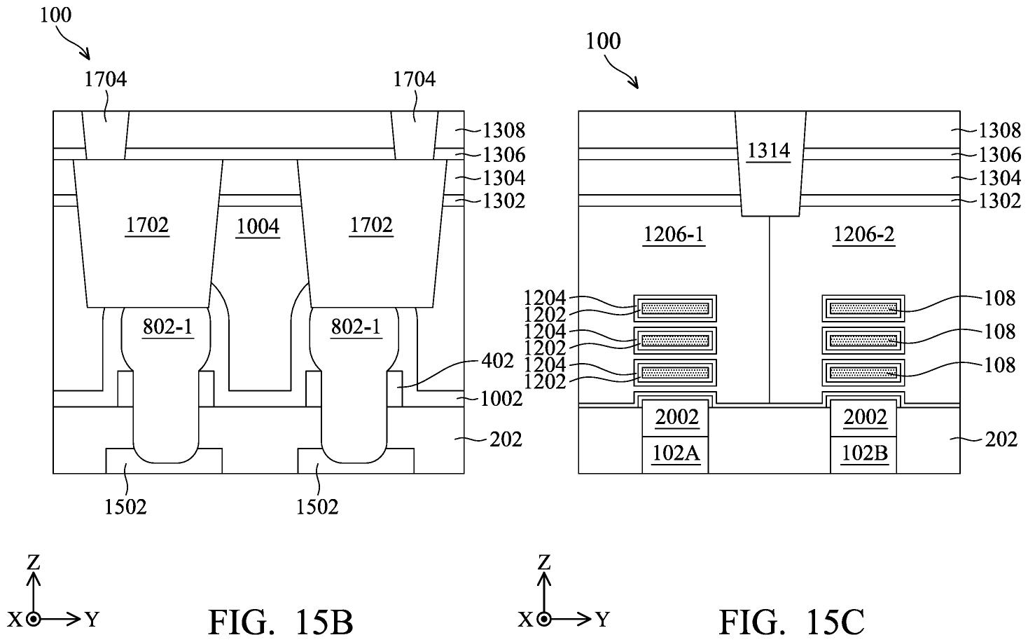

In some embodiments, referring to FIGS. 15A to 15C, dielectric layers 2002 are formed directly under the gate structures 1208 in the Z-direction. The dielectric layers 2002 are in contact with the gate structures 1208. The dielectric layers 2002 are rectangle in the X-Z cross-sectional view shown in FIG. 15A and in the Y-Z cross-sectional view shown in FIG. 15C. In some embodiments, a width of the dielectric layers 2002 in the X-direction and a gate length of the gate structures 1208 in the X-direction (“gate length” generally refers to the size of the gate structure between two source/drain features) are the same. The dielectric layers 2002 further enhance the isolation of the gate structures 1208 from the source/drain features 802-1 and 802-2. The dielectric layers 2002 includes a dielectric material nitride, such as Si3N4, SiO2, SiC, SiOC, SiON, SiCN, SiOCN, carbon doped oxide, nitrogen doped oxide, porous oxide, or combinations thereof.

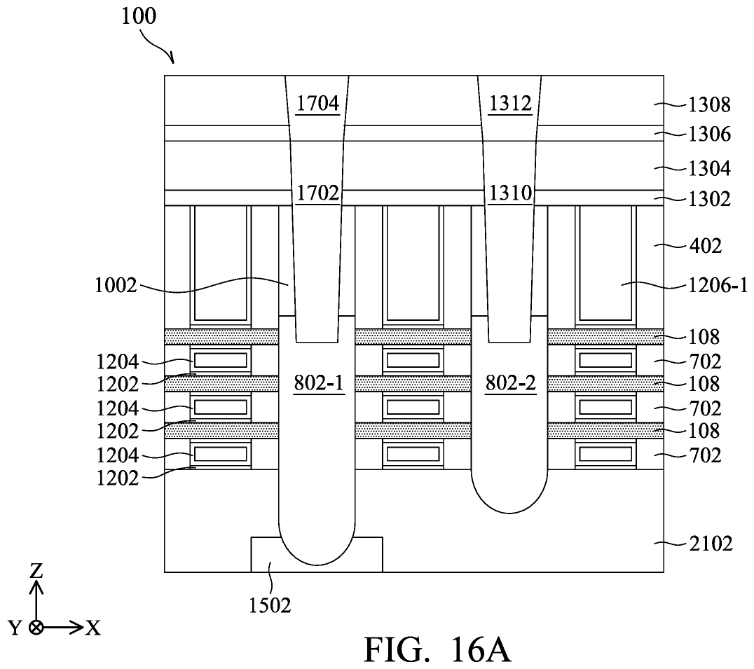

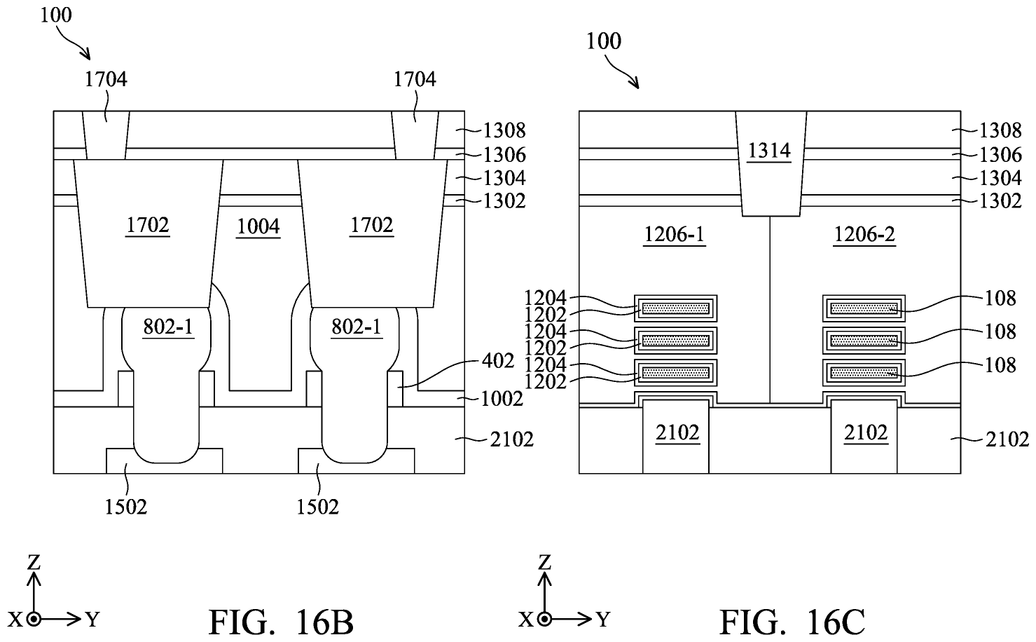

In some embodiments, referring to FIGS. 16A to 16C, a dielectric layer 2102 replaces the substrate 102. Specifically, instead of thinning the substrate 102 (as shown in FIGS. 1N-1 to 1N-3), the substrate 102 is fully removed from workpiece 100 by one or more etching processes, and then the dielectric layer 2102 is formed under the gate structures 1208, the semiconductor layers 108, and the source/drain features 802-1 and 802-2. The vias 1502 are formed after the formation of the dielectric layer 2102. The formation of the vias 1502 shown in FIGS. 16A to 16C is similar to above discussion, except that the openings 1402 for the vias 1502 are formed by performing one or more lithography and etching processes on a bottom surface of the dielectric layer 2102 (or on back-side of the dielectric layer 2102). Therefore, the vias 1502 are formed in the dielectric layer 2102 and in contact with the source/drain features 802-1 and 802-2, the isolation structure 202, and the dielectric layer 2102. The dielectric layers 2102 further enhance the isolation between the source/drain features 802-1 and 802-2 and the gate structures 1208. The dielectric layer 2102 includes a dielectric material nitride, such as Si3N4, SiO2, SiC, SiOC, SiON, SiCN, SiOCN, carbon doped oxide, nitrogen doped oxide, porous oxide, or combinations thereof. It should be noted that features discussed above may be combined in any way.

The embodiments disclosed herein relate to semiconductor structures and their manufacturing methods, and more particularly to methods and semiconductor structures comprising deeper and larger depth source/drain features and back-side sheet vias in contact with bottom surfaces of the deeper and larger depth source/drain features to prevent short-circuits between the back-side vias and gate structures caused by process variation. Furthermore, the present embodiments provide one or more of the following advantages. The back-side sheet vias formed under the deeper and larger depth source/drain features provides larger process window and lower resistance, which improves the performance of the transistors, such as RC delay.

Thus, one of the embodiments of the present disclosure describes a method for manufacturing a semiconductor structure that includes forming a fin over a substrate in a Z-direction. The fin includes first semiconductor layers and second semiconductor layers alternating stacked. The method further includes forming a dummy gate structure extending in a Y-direction and over the fin, forming a first source/drain feature and a second source/drain feature on opposite sides of the dummy gate structure in an X-direction, removing the dummy gate structure and the first semiconductor layers in the fin to form a gate trench, and forming a gate structure in the gate trench. The gate structure wraps around the second semiconductor layers. The method further includes forming a via in contact with a bottom surface of the first source/drain feature. The bottom surface of the first source/drain feature is lower than a bottom surface of the second source/drain feature.

In some embodiments, a ratio of a width of the via in the X-direction to a thickness of the via in the Z-direction is greater than 1.

In some embodiments, the via extends directly under the gate structure in the Z-direction.

In some embodiments, the formation of the via includes performing a chemical mechanical polishing process to thin the substrate, removing the substrate directly under the first source/drain feature and a portion of the first source/drain feature to form an opening, and filling the opening with a conductive material to form the via.

In some embodiments, the via has a concave surface in contact with the bottom surface of the first source/drain feature.

In some embodiments, the formation of the first source/drain feature and the second source/drain feature includes implanting dopants in a first region, etching the first region and a second region of the fin simultaneously to form a first source/drain trench in the first region and a second source/drain trench in the second region, and forming the first source/drain feature in the first source/drain trench and the second source/drain feature in the second source/drain trench.

In some embodiments, a length of the via in the Y-direction is greater than a length of the first source/drain feature in the Y-direction.

In some embodiments, a distance from the bottom surface of the first source/drain feature to the bottom surface of the second source/drain feature in the Z-direction is in a range from about 10 nm to about 50 nm.

In some embodiments, the method further includes forming a source/drain contact over and electrically connected to the first source/drain feature.

In another of the embodiments, discussed is a method for manufacturing a semiconductor structure including forming fins over a substrate in a Z-direction. Each of the fins includes first semiconductor layers and second semiconductor layers alternating stacked. The method further includes forming an isolation structure between the fins, forming a dummy gate structure extending in a Y-direction and over the fins and the isolation structure, and forming first source/drain features and second source/drain features in the fins. A thickness of the first source/drain features is greater than a thickness of the second source/drain features. The method further includes removing the dummy gate structure and the first semiconductor layers in the fins to expose the second semiconductor layers, forming a gate structure wrapping around the exposed second semiconductor layers, and forming vias in contact with the first source/drain features and the isolation structure. A width of the vias in a X-direction is greater than a thickness of the vias in the Z-direction.

In some embodiments, the first source/drain features have substantially flat bottom surfaces.

In some embodiments, the first source/drain features have convex bottom surfaces.

In some embodiments, the first source/drain features are in contact with sidewalls of the vias.

In some embodiments, top surfaces of the vias are in contact with the isolation structure.

In some embodiments, the vias are square in a top view and the width of the vias is in a range from about 6 nm to about 200 nm.

In some embodiments, the formation of the vias includes removing the substrate, forming a dielectric layer under the first source/drain features, the second first source/drain features, and the gate structures, and forming the vias in the dielectric layer and in contact with the first source/drain features, the isolation structure, and the dielectric layer.

In yet another of the embodiments, discussed is a semiconductor structure that includes a substrate, nanostructures, a gate structure, a first source/drain feature and a second source/drain feature, and a via. The nanostructures are over the substrate and spaced apart from each other in a Z-direction. The gate structure extends in a Y-direction and wraps around the nanostructures. The first source/drain feature and the second source/drain feature are on opposite sides of the gate structures in an X-direction and connected to the nanostructures. A bottom surface of the first source/drain feature is lower than a bottom surface of the second source/drain feature. A via is in contact with the bottom surface of the first source/drain feature.

In some embodiments, the semiconductor structure further includes a dielectric layer directly under and in contact with the second source/drain feature in the Z-direction.

In some embodiments, the semiconductor structure further includes a dielectric layer directly under and in contact with the gate structure in the Z-direction.

In some embodiments, the semiconductor structure further includes a dielectric layer in contact with sidewalls of the first source/drain feature, the second source/drain feature, the nanostructures, and the via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a fin over a substrate in a Z-direction, wherein the fin comprises first semiconductor layers and second semiconductor layers alternating stacked;
forming a dummy gate structure extending in a Y-direction and over the fin;
forming a first source/drain feature and a second source/drain feature on opposite sides of the dummy gate structure in an X-direction;
removing the dummy gate structure and the first semiconductor layers in the fin to form a gate trench;
forming a gate structure in the gate trench, wherein the gate structure wraps around the second semiconductor layers; and
forming a via in contact with a bottom surface of the first source/drain feature, wherein the bottom surface of the first source/drain feature is lower than a bottom surface of the second source/drain feature.

2. The method of claim 1, wherein a ratio of a width of the via in the X-direction to a thickness of the via in the Z-direction is greater than 1.

3. The method of claim 1, wherein the via extends directly under the gate structure in the Z-direction.

4. The method of claim 1, wherein the formation of the via comprises:
performing a chemical mechanical polishing process to thin the substrate;
removing the substrate directly under the first source/drain feature and a portion of the first source/drain feature to form an opening; and
filling the opening with a conductive material to form the via.

5. The method of claim 1, wherein the via has a concave surface in contact with the bottom surface of the first source/drain feature.

6. The method of claim 1, wherein the formation of the first source/drain feature and the second source/drain feature comprises:
implanting dopants in a first region;
etching the first region and a second region of the fin simultaneously to form a first source/drain trench in the first region and a second source/drain trench in the second region; and
forming the first source/drain feature in the first source/drain trench and the second source/drain feature in the second source/drain trench.

7. The method of claim 1, wherein a length of the via in the Y-direction is greater than a length of the first source/drain feature in the Y-direction.

8. The method of claim 1, wherein a distance from the bottom surface of the first source/drain feature to the bottom surface of the second source/drain feature in the Z-direction is in a range from about 10 nm to about 50 nm.

9. The method of claim 1, further comprising:
forming a source/drain contact over and electrically connected to the first source/drain feature.

10. A method for manufacturing a semiconductor structure, comprising:
forming fins over a substrate in a Z-direction, wherein each of the fins comprises first semiconductor layers and second semiconductor layers alternating stacked;
forming an isolation structure between the fins;
forming a dummy gate structure extending in a Y-direction and over the fins and the isolation structure;
forming first source/drain features and second source/drain features in the fins, wherein a thickness of the first source/drain features is greater than a thickness of the second source/drain features;
removing the dummy gate structure and the first semiconductor layers in the fins to expose the second semiconductor layers;
forming a gate structure wrapping around the exposed second semiconductor layers; and
forming vias in contact with the first source/drain features and the isolation structure, wherein a width of the vias in a X-direction is greater than a thickness of the vias in the Z-direction.

11. The method of claim 10, wherein the first source/drain features have substantially flat bottom surfaces.

12. The method of claim 10, wherein the first source/drain features have convex bottom surfaces.

13. The method of claim 10, wherein the first source/drain features are in contact with sidewalls of the vias.

14. The method of claim 10, wherein top surfaces of the vias are in contact with the isolation structure.

15. The method of claim 10, wherein the vias are square in a top view and the width of the vias is in a range from about 6 nm to about 200 nm.

16. The method of claim 10, wherein the formation of the vias comprises:
removing the substrate;
forming a dielectric layer under the first source/drain features, the second first source/drain features, and the gate structures; and
forming the vias in the dielectric layer and in contact with the first source/drain features, the isolation structure, and the dielectric layer.

17. A semiconductor structure, comprising:
a substrate;
nanostructures over the substrate and spaced apart from each other in a Z-direction;
a gate structure extending in a Y-direction and wrapping around the nanostructures;
a first source/drain feature and a second source/drain feature on opposite sides of the gate structures in an X-direction and connected to the nanostructures, wherein a bottom surface of the first source/drain feature is lower than a bottom surface of the second source/drain feature; and
a via in contact with the bottom surface of the first source/drain feature.

18. The semiconductor structure of claim 17, further comprising:
a dielectric layer directly under and in contact with the second source/drain feature in the Z-direction.

19. The semiconductor structure of claim 17, further comprising:
a dielectric layer directly under and in contact with the gate structure in the Z-direction.

20. The semiconductor structure of claim 17, further comprising:
a dielectric layer in contact with sidewalls of the first source/drain feature, the second source/drain feature, the nanostructures, and the via.
